(19) United States
(12) Patent Application Publication
(10) Pub. No.: US 2018/0012666 A1
(43) Pub. Date: Jan. 11, 2018

(54) MEMORY SYSTEM AND OPERATING METHOD THEREOF

(71) Applicant: SK hynix Inc., Gyeonggi-do (KR)

(72) Inventor: Hyoun-Ju KIM, Gyeonggi-do (KR)

(21) Appl. No.: 15/434,338

(22) Filed: Feb. 16, 2017

(30) Foreign Application Priority Data
Jul. 7, 2016 (KR) 10-2016-0086050

(51) Int. Cl. G11C 16/34; G11C 16/04; G11C 16/10; G06F 3/06; G11C 16/24; G11C 16/16

(52) U.S. Cl. CPC G11C 16/349; G11C 16/24; G11C 16/16; G11C 16/10; G06F 3/0604; G06F 3/068; G06F 3/0655; G11C 16/0483

(57) ABSTRACT

A memory system may include: a memory device including a plurality of pages, each page including a plurality of memory cells coupled with a word line, a plurality of memory blocks in which the pages are included, a plurality of planes which include the memory blocks, and a plurality of memory dies in which the planes are included; and a controller suitable for performing at least one of a foreground operation and a background operation for the memory blocks, for checking parameters of the respective memory blocks in correspondence to performing the at least one of the foreground operation and the background operation, generating normalized parameters of the respective memory blocks, and performing the foreground operation and the background operation by using the normalized parameters of the respective memory blocks.

### CROSS-REFERENCE TO RELATED APPLICATION

This application claims priority under 35 U.S.C. §119(a) to Korean Patent Application No. 10-2016-0086050 filed on Jul. 7, 2016 in the Korean Intellectual Property Office (KIPO), the disclosure of which is incorporated herein by reference in its entirety.

### TECHNICAL FIELD

Exemplary embodiments of the present invention relate to a memory system which processes data with respect to a memory device, and an operating method thereof.

### DISCUSSION OF THE RELATED ART

The computer environment paradigm has shifted to ubiquitous computing systems that can be used anytime and anywhere. Due to this, use of portable electronic devices such as mobile phones, digital cameras, and notebook computers has rapidly increased. These portable electronic devices generally use a memory system having one or more memory devices for storing data. The memory system may be used as a main memory device or an auxiliary memory device of a portable electronic device.

Memory systems using memory devices provide excellent stability, durability, high information access speed, and low power consumption, since they have no moving parts. Examples of memory systems having such advantages include universal serial bus (USB) memory devices, memory cards having various interfaces, and solid state drives (SSD).

### SUMMARY

Various embodiments are directed to a memory system and an operating method thereof, capable of minimizing complexity and performance deterioration of a memory system and maximizing use efficiency of a memory device, thereby quickly and stably processing data with respect to the memory device.

In an embodiment of the present invention, a memory device including a plurality of pages, each page including a plurality of memory cells coupled with a word line, a plurality of memory blocks in which the pages are included, a plurality of planes which include the memory blocks, and a plurality of memory dies in which the planes are included; and a controller suitable for performing at least one of a foreground operation and a background operation for the memory blocks, for checking parameters of the respective memory blocks in correspondence to performing the at least one of the foreground operation and the background operation, generating normalized parameters of the respective memory blocks, and performing the foreground operation and the background operation by using the normalized parameters of the respective memory blocks.

The controller may set, in correspondence to performing the at least one of the foreground operation and the background operation, weights for the respective memory blocks, and may normalize the parameters of the respective memory blocks by granting the weights to the parameters of the respective memory blocks.

The weights for the respective memory blocks depend upon the stress levels in the respective memory blocks, when performing the at least one of the foreground operation and the background operation.

The stress levels for the respective memory blocks depend upon at least one of an operational characteristic and a structural characteristic of the respective memory blocks.

Among the memory blocks, the controller may set a first weight to first memory blocks which have a first stress level, may set a second weight to second memory blocks which have a second stress level, and may set a third weight to third memory blocks which have a third stress level.

The first memory blocks may be single level cell (SLC) memory blocks, the second memory blocks may be multi-level cell (MLC) memory blocks, and the third memory blocks may be triple level cell (TLC) memory blocks.

After performing the at least one of the foreground operation and the background operation by using the normalized parameters, the controller may update the parameters and the normalized parameters of the respective memory blocks.

The foreground operation may include at least one of a program operation, a read operation, an erase operation and a parameter set operation for the memory blocks, and the background operation may include at least one of a data copy operation, a data swap operation, a map flush operation and a bad block management operation for the memory blocks.

The controller may select a first memory block and a second memory block among the memory blocks, by using the normalized parameters of the respective memory blocks, and may perform the data copy operation or the data swap operation for the first memory block and the second memory block.

The at least one parameter includes an operation parameter and a state parameter in the respective memory blocks when performing the foreground operation and the background operation.

In an embodiment of the present invention, a method for operating a memory system may include: performing at least one of a foreground operation and a background operation for a plurality of memory blocks of a memory device, including a plurality of pages each page including a plurality of memory cells which are coupled to a word line; checking a parameter for each of the respective memory blocks in correspondence to performing the foreground operation and the background operation; normalizing the parameters of the respective memory blocks and generating a normalized parameter for each of the respective memory blocks; and performing the at least one of the foreground operation and the background operation by using the normalized parameter for each of the respective memory blocks.

The method may further include: setting, in correspondence to performing the at least one of the foreground operation and the background operation, a weight for each of the respective memory blocks. The generating of the normalized parameter may include normalizing the parameter for each of respective memory blocks by granting the weights to the parameters of the respective memory blocks.

The setting of the weight may include setting the weight for each of the respective memory blocks depending upon a stress level for each of the respective memory blocks, when performing the at least one of the foreground operation and the background operation.

The stress level for each of the respective memory blocks may depend upon at least one of an operational characteristic and a structural characteristic for each of the respective memory blocks.

The setting of the weight may include setting a first weight for first memory blocks which have a first stress level, setting a second weight for second memory blocks which have a second stress level, and setting a third weight for third memory blocks which have a third stress level.

The first memory blocks may be single level cell (SLC) memory blocks, the second memory blocks may be multi-level cell (MLC) memory blocks, and the third memory blocks may be triple level cell (TLC) memory blocks.

The method may further include: updating the parameter and the normalized parameter for each of the respective memory blocks, after performing the at least one of the foreground operation and the background operation by using the normalized parameters.

The foreground operation may include at least one of a program operation, a read operation, an erase operation and a parameter set operation for the memory blocks, and the background operation may include at least one of a data copy operation, a data swap operation, a map flush operation and a bad block management operation in the memory blocks.

The performing of the background operation may include: selecting a first memory block and a second memory block among the memory blocks, by using the normalized parameters of the respective memory blocks; and performing the data copy operation or the data swap operation for the first memory block and the second memory block.

The parameter may include at least one of an operation parameter and a state parameter for each of the respective memory blocks when performing the at least one of the foreground operation and the background operation.

In an embodiment of the present invention, a method for operating a memory system may include: providing a first memory block including a first type memory cell, a second memory block including a second type memory cell different from the first type memory cell, and a controller coupled to the first and second memory blocks; setting weights of respectively different magnitudes in correspondence to memory cell types in the first and second memory blocks; generating normalized parameters of the first and second memory blocks by granting the weights to parameters of the first and second memory blocks; and performing a foreground operation and a background operation by using the normalized parameters of the first and second memory blocks.

### BRIEF DESCRIPTION OF THE DRAWINGS

These and other features and advantages of the present invention will become apparent to persons skilled in the art to which this invention pertains from the following detailed description of various embodiments of the present invention in reference to the accompanying drawings, wherein:

FIG. 1 is a diagram illustrating a data processing system including a memory system coupled to a host, according to an embodiment of the present invention.

FIG. 2 is a diagram illustrating a memory device employed in the memory system of FIG. 1, according to an embodiment of the present invention.

FIG. 3 is a diagram illustrating a memory cell array circuit of a memory block in a memory device, according to an embodiment of the present invention.

FIG. 4 is a diagram illustrating a structure of the memory device in a memory system, according to an embodiment of the present invention.

FIGS. 5 to 7 are representations of examples of diagrams of a data processing operation with respect to a memory device in a memory system according to an embodiment.

FIG. 8 is a flow chart of an operation process for processing data in a memory system according to an embodiment.

FIGS. 9 to 14 are diagrams illustrating memory systems, according to various embodiments of the present invention.

### DETAILED DESCRIPTION

Although, various embodiments are described below in more detail with reference to the accompanying drawings, we note that the present invention may, however, be embodied in different forms and should not be construed as being limited only to the embodiments set forth herein. Rather, the described embodiments are provided so that this disclosure will be thorough and complete, and will fully convey the present invention to those skilled in the art to which this invention pertains. Throughout the disclosure, like reference numerals refer to like parts throughout the various figures and embodiments of the present invention.

It will be understood that, although the terms “first”, “second”, “third”, and so on may be used herein to describe various elements, these elements are not limited by these terms. These terms are used to distinguish one element from another element. Thus, a first element described below could also be termed as a second or third element without departing from the spirit and scope of the present invention.

The drawings are not necessarily to scale and, in some instances, proportions may have been exaggerated in order to clearly illustrate features of the embodiments.

It will be further understood that when an element is referred to as being “connected to”, or “coupled to” another element, it may be directly on, connected to, or coupled to the other element, or one or more intervening elements may be present. In addition, it will also be understood that when an element is referred to as being “between” two elements, it may be the only element between the two elements, or one or more intervening elements may also be present.

The terminology used herein is for the purpose of describing particular embodiments only and is not intended to be limiting of the present invention.

As used herein, singular forms are intended to include the plural forms as well, unless the context clearly indicates otherwise.

It will be further understood that the terms “comprises,” “comprising,” “includes,” and “including” when used in this specification, specify the presence of the stated elements and do not preclude the presence or addition of one or more other elements. As used herein, the term “and/or” includes any and all combinations of one or more of the associated listed items.

Unless otherwise defined, all terms including technical and scientific terms used herein have the same meaning as commonly understood by one of ordinary skill in the art to which the present invention belongs in view of the present disclosure. It will be further understood that terms, such as those defined in commonly used dictionaries, should be interpreted as having a meaning that is consistent with their meaning in the context of the present disclosure and the relevant art and will not be interpreted in an idealized or overly formal sense unless expressly so defined herein.

We further note that in the following description, numerous specific details are set forth in for providing a thorough understanding of the present invention. However, as would be apparent to those skilled in the relevant art, the present invention may be practiced without some or all of these specific details. In other instances, well-known process structures and/or processes have not been described in detail in order not to unnecessarily obscure the present invention.

It is also noted, that in some instances, as would be apparent to those skilled in the relevant art, a feature or element described in connection with one embodiment may be used singly or in combination with other features or elements of another embodiment, unless otherwise specifically indicated.

Hereinafter, the various embodiments of the present invention will be described with reference to the attached drawings.

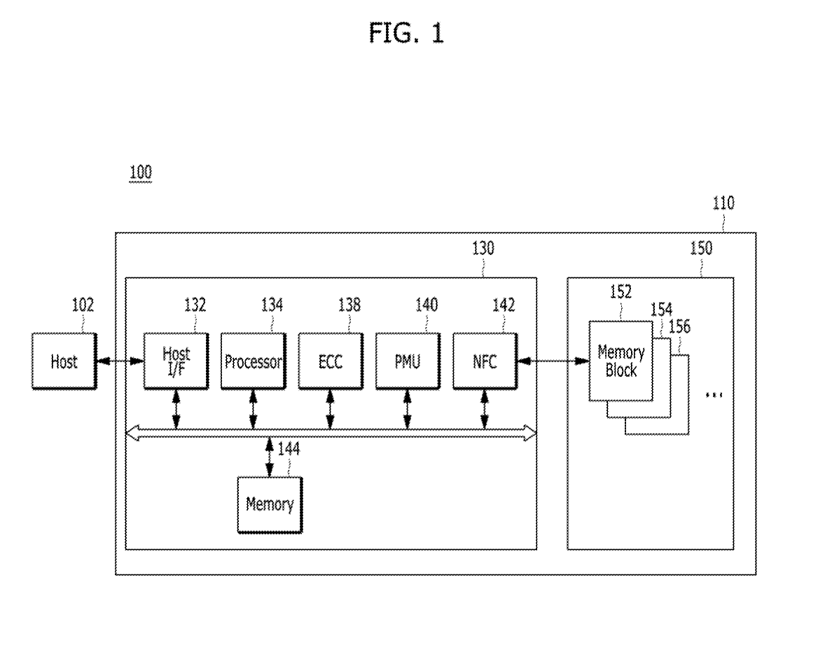

FIG. 1 illustrates a data processing system 100 including a memory system 110, according to an embodiment of the present invention.

Referring to FIG. 1, a data processing system 100 may include a host 102 operatively coupled to a memory system 110.

The host 102 may include, for example, a portable electronic device such as a mobile phone, an MP3 player and a laptop computer or a non-portable electronic device such as a desktop computer, a game player, a TV and a projector.

The memory system 110 may operate in response to a request received from the host 102. For example, the memory system 110 may store data to be accessed by the host 102. The memory system 110 may be used as a main memory system or an auxiliary memory system of the host 102. The memory system 110 may be implemented with any one of various storage devices, according to the protocol of a host interface to be coupled electrically with the host 102. The memory system 110 may be implemented with any one of various storage devices, such as, for example, a solid state drive (SSD), a multimedia card (MMC), an embedded MMC (eMMC), a reduced size MMC (RS-MMC), a micro-MMC, a secure digital (SD) card, a mini-SD, a micro-SD, a universal serial bus (USB) storage device, a universal flash storage (UFS) device, a compact flash (CF) card, a smart media (SM) card, a memory stick, and the like.

The storage devices for the memory system 110 may be implemented with a volatile memory device, such as, a dynamic random access memory (DRAM) and a static random access memory (SRAM) or a nonvolatile memory device such as a read only memory (ROM), a mask ROM (MROM), a programmable ROM (PROM), an erasable programmable ROM (EPROM), an electrically erasable programmable ROM (EEPROM), a ferroelectric random access memory (FRAM), a phase-change RAM (PRAM), a magnetoresistive RAM (MRAM), a resistive RAM (RRAM), and a flash memory.

The memory system 110 may include a memory device 150 for storing data to be accessed by the host 102, and a controller 130 operatively coupled to the memory device 150 for controlling the storage of data in the memory device 150 and the transfer of stored data from the memory device to the host.

The controller 130 and the memory device 150 may be integrated into a single semiconductor device. For instance, the controller 130 and the memory device 150 may be integrated into a single semiconductor device configured as a solid state drive (SSD). When the memory system 110 is used as the SSD, the operation speed of the host 102 that is electrically coupled with the memory system 110 may be significantly increased.

The controller 130 and the memory device 150 may be integrated into a single semiconductor device configured as a memory card, such as, for example, a Personal Computer Memory Card International Association (PCMCIA) card, a compact flash (CF) card, a smart media card (SMC), a memory stick, a multimedia card (MMC), an RS-MMC, a micro-MMC, a secure digital (SD) card, a mini-SD, a micro-SD, an SDHC, and a universal flash storage (UFS) device.

For another instance, the memory system 110 may be configured as part of a computer, an ultra-mobile PC (UMPC), a workstation, a net-book, a personal digital assistant (PDA), a portable computer, a web tablet, a tablet computer, a wireless phone, a mobile phone, a smart phone, an e-book, a portable multimedia player (PMP), a portable game player, a navigation device, a black box, a digital camera, a digital multimedia broadcasting (DMB) player, a three-dimensional (3D) television, a smart television, a digital audio recorder, a digital audio player, a digital picture recorder, a digital picture player, a digital video recorder, a digital video player, a storage configuring a data center, a device capable of transmitting and receiving information under a wireless environment, one of various electronic devices configuring a home network, one of various electronic devices configuring a computer network, one of various electronic devices configuring a telematics network, an RFID device, or one of various component elements configuring a computing system.

The memory device 150 of the memory system 110 may retain stored data when power supply to the device is interrupted and, in particular, store the data provided from the host 102 during a write operation, and provide stored data to the host 102 during a read operation. The memory device 150 may include a plurality of memory blocks, for example, memory blocks 152, 154 and 156. Each of the memory blocks 152, 154 and 156 may include a plurality of pages. Each of the pages may include a plurality of memory cells coupled to a word line (WL). The memory device 150 may be a nonvolatile memory device, for example, a flash memory. The flash memory may have a three-dimensional (3D) stack structure. The structure of the memory device 150 and the three-dimensional (3D) stack structure of the memory device 150 will be described later.

The controller 130 of the memory system 110 may control the memory device 150 in response to a request from the host 102. For example, upon receiving a read request from the host 102 the controller 130 may issue a read command and an address to the memory device for reading the data which are stored in the requested address in the memory device and may provide the data read from the memory device 150, to the host 102. Also, in response to a program request (also referred to as a write request) received from the host 102, the controller 130 may issue a write command, an address and write data and may control the operation of the memory device for storing the write data into the memory device 150. The write data are provided from the host 102 to the memory controller together with the write request. To this end, the controller 130 may control one or more operations of the memory device 150 including, for example, a read operation, a write operation and an erase operation. The controller 130 may also control one or more background operations of the memory device 150.

In the illustrated embodiment of FIG. 1, the controller 130 includes a host interface unit 132, a processor 134, an error correction code (ECC) unit 138, a power management unit (PMU) 140, a NAND flash controller (NFC) 142, and a memory 144.

The host interface unit 132 provides an interface between the host and the controller 130. For example, the host interface 132 may receive and process requests, addresses and data provided from the host 102. The host interface may also transmit read data from the memory device to the host. The host interface 132 may communicate with the host 102 through at least one of various well-known interface protocols such as a universal serial bus (USB), a multimedia card (MMC), a peripheral component interconnect-express (PCI-E), a serial attached SCSI (SAS), a serial advanced technology attachment (SATA), a parallel advanced technology attachment (PATA), small computer system interface (SCSI), enhanced small disk interface (ESDI), and integrated drive electronics (IDE).

The ECC unit 138 may detect and correct errors in the data read from the memory device 150 during the read operation. The ECC unit 138 may not correct error bits when the number of the error bits is greater than or equal to a threshold number of correctable error bits, and may output an error correction fail signal indicating failure in correcting the error bits.

The ECC unit 138 may perform an error correction operation based on a coded modulation such as a low density parity check (LDPC) code, a Bose-Chaudhuri-Hocquenghem (BCH) code, a turbo code, a Reed-Solomon (RS) code, a convolution code, a recursive systematic code (RSC), a trellis-coded modulation (TCM), a Block coded modulation (BCM), and so on. The ECC unit 138 may include all circuits, systems or devices for the error correction operation.

The PMU 140 may provide and manage power for the controller 130, that is, power for the component elements included in the controller 130.

The NFC 142 may serve as a memory interface between the controller 130 and the memory device 150 to allow the controller 130 to control the memory device 150 in response to a request from the host 102. The NFC 142 may generate control signals for the memory device 150 and process data under the control of the processor 134 when the memory device 150 includes a flash memory and, in particular, when the memory device 150 includes a NAND flash memory.

The memory 144 may serve as a working memory of the memory system 110 and the controller 130, and store data for driving the memory system 110 and the controller 130. The controller 130 may control the memory device 150 in response to a request from the host 102. For example, the controller 130 may provide the data read from the memory device 150 to the host 102 and store the data provided from the host 102 in the memory device 150. When the controller 130 controls the operations of the memory device 150, the memory 144 may store data used by the controller 130 and the memory device 150 for such operations as read operation, write operation, program operation and erase operation.

The memory 144 may be implemented with volatile memory. The memory 144 may be implemented with a static random access memory (SRAM) or a dynamic random access memory (DRAM). As described above, the memory 144 may store data used by the host 102 and the memory device 150 for the read and write operations. To store the data, the memory 144 may include a program memory, a data memory, a write buffer, a read buffer, a map buffer, and so forth.

The processor 134 may control general operations of the memory system 110, and a write operation or a read operation for the memory device 150, in response to a write request or a read request from the host 102. The processor 134 may drive firmware, which is referred to as a flash translation layer (FTL), to control the general operations of the memory system 110. The processor 134 may be implemented with a microprocessor or a central processing unit (CPU).

A management unit (not shown) may be included in the processor 134, and may perform bad block management of the memory device 150. The management unit may find bad memory blocks included in the memory device 150, which are in unsatisfactory condition for further use, and perform bad block management on the bad memory blocks. When the memory device 150 is a flash memory, for example, a NAND flash memory, a program failure may occur during the write operation, for example, during the program operation, due to characteristics of a NAND logic function. During the bad block management, the data of the program-failed memory block or the bad memory block may be programmed into a new memory block. Also, the bad blocks due to the program fail seriously deteriorates the utilization efficiency of the memory device 150 having a 3D stack structure and the reliability of the memory system 100, and thus reliable bad block management is required.

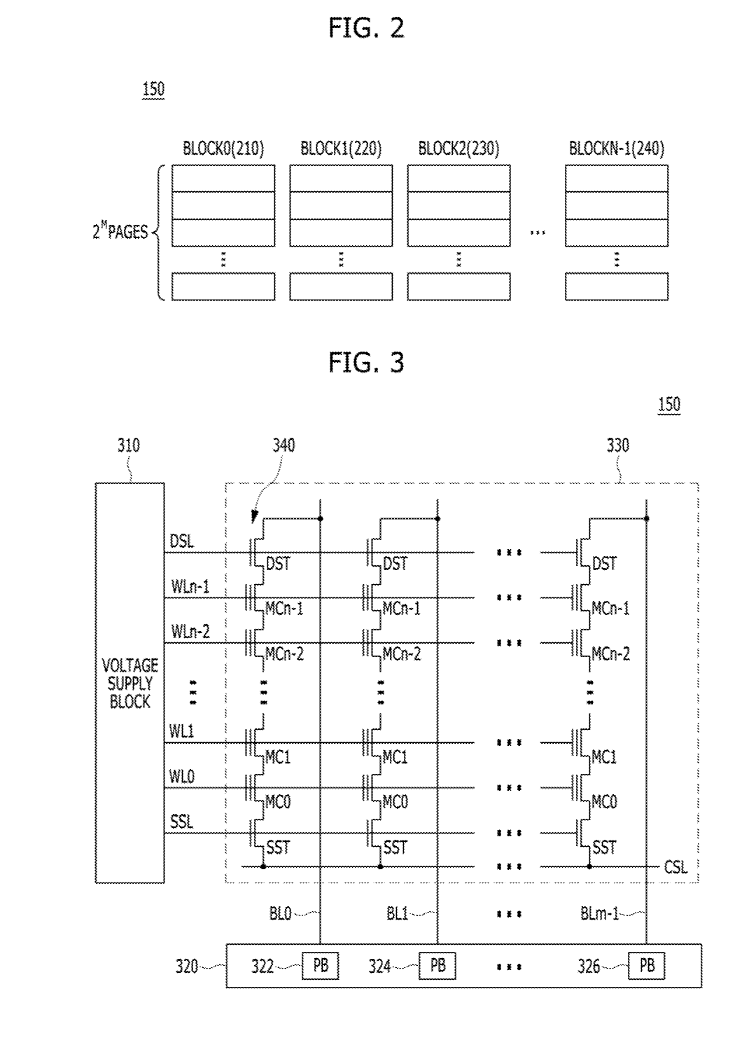

FIG. 2 is a schematic diagram illustrating the memory device 150 of FIG. 1.

Referring to FIG. 2, the memory device 150 may include a plurality of memory blocks, for example, zeroth to (N−1)^{th} blocks 210 to 240. Each of the plurality of memory blocks 210 to 240 may include a plurality of pages, for example, 2^{M} number of pages (2^{M} PAGES), to which the present invention will not be limited. Each of the plurality of pages may include a plurality of memory cells to which a plurality of word lines are electrically coupled.

Also, the memory device 150 may include a plurality of memory blocks, as single level cell (SLC) memory blocks and multi-level cell (MLC) memory blocks, according to the number of bits which may be stored or expressed in each memory cell. The SLC memory block may include a plurality of pages which are implemented with memory cells each capable of storing 1-bit data. The MLC memory block may include a plurality of pages which are implemented with memory cells each capable of storing multi-bit data, for example, two or more-bit data. The MLC memory block including a plurality of pages which are implemented with memory cells that are each capable of storing 3-bit data may be defined as a triple level cell (TLC) memory block.

Each of the plurality of memory blocks 210 to 240 may store the data provided from the host device 102 during a write operation, and may provide stored data to the host 102 during a read operation.

FIG. 3 is a circuit diagram illustrating an example of a memory block in a memory device.

Referring to FIG. 3, a memory block 330 of a memory device 300 may include a plurality of cell strings 340 which are realized into a memory cell array and are coupled to bit lines BL0 to BLm-1, respectively. The cell string 340 of each column may include at least one drain select transistor DST and at least one source select transistor SST. A plurality of memory cells or memory cell transistors MC0 to MCn-1 may be coupled in series between the select transistors DST and SST. The respective memory cells MC0 to MCn-1 may be constructed by multi-level cells (MLC) each of which stores a data information of a plurality of bits. The cell strings 340 may be electrically coupled to corresponding bit lines BL0 to BLm-1, respectively. For reference, in FIG. 3, ‘DSL’ may denote a drain select line, ‘SSL’ may denote a source select line, and ‘CSL’ may denote a common source line.

While FIG. 3 shows, as an example, the memory block 330 which is constructed by NAND flash memory cells, it is to be noted that the memory block 330 of the memory device 300 according to the embodiment is not limited to a NAND flash memory and may be realized by a NOR flash memory, a hybrid flash memory in which at least two kinds of memory cells are combined or a one-NAND flash memory in which a controller is built in a memory chip. The operational characteristics of a semiconductor device may be applied to not only a flash memory device in which a charge storing layer is constructed by conductive floating gates but also a charge trap flash (CTF) in which a charge storing layer is constructed by a dielectric layer.

A voltage supply block 310 of the memory device 300 may provide word line voltages (for example, a program voltage, a read voltage and a pass voltage) to be supplied to respective word lines according to an operation mode and voltages to be supplied to bulks (for example, well regions) formed with memory cells. The voltage generating operation of the voltage supply block 310 may be performed by the control of a control circuit (not shown). The voltage supply block 310 may generate a plurality of variable read voltages to generate a plurality of read data, select one of the memory blocks (or sectors) of a memory cell array in response to the control of the control circuit, select one of the word lines of the selected memory block, and provide the word line voltages to the selected word line and unselected word lines.

A read/write circuit 320 of the memory device 300 is controlled by the control circuit, and may operate as a sense amplifier or a write driver according to an operation mode. For example, in the case of a verify/normal read operation, the read/write circuit 320 may operate as a sense amplifier for reading data from the memory cell array. Also, in the case of a program operation, the read/write circuit 320 may operate as a write driver which drives bit lines according to data to be stored in the memory cell array. In the program operation, the read/write circuit 320 may receive data to be written in the memory cell array, from a buffer (not shown), and may drive the bit lines according to inputted data. To this end, the read/write circuit 320 may include a plurality of page buffers (PB) 322, 324 and 326 respectively corresponding to columns (or bit lines) or pairs of columns (or pairs of bit lines), and a plurality of latches (not shown) may be included in each of the page buffers 322, 324 and 326.

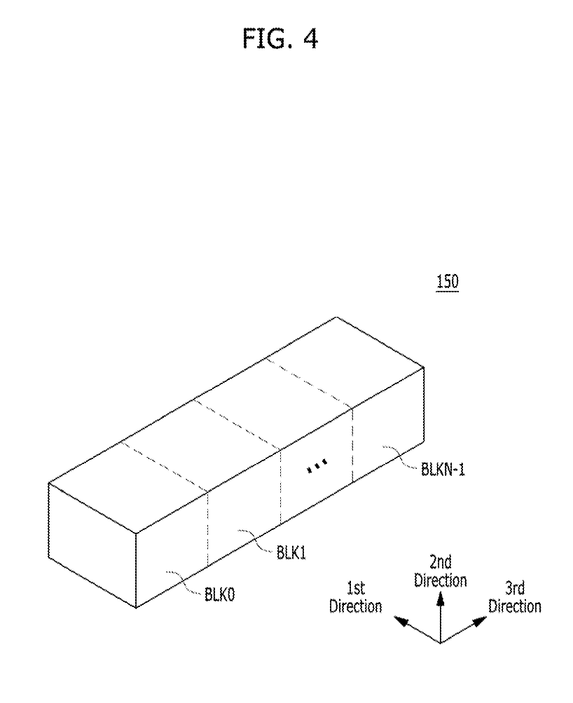

Also, the memory device 150 may be realized as a 2-dimensional or 3-dimensional memory device. As shown in FIG. 4, in the case where the memory device 150 is realized as a 3-dimensional nonvolatile memory device, the memory device 150 may include a plurality of memory blocks BLK0 to BLKN-1.

FIG. 4 is a block diagram illustrating the memory blocks of the memory device shown in FIG. 2, and the memory blocks BLK0 to BLKN-1 may be realized as a 3-dimensional structure (or a vertical structure). For example, the respective memory blocks BLK0 to BLKN-1 may be realized as a 3-dimensional structure by including a structure which extends in first to third directions, for example, the x-axis direction, the y-axis direction and the z-axis direction.

The respective memory blocks BLK0 to BLKN-1 included in the memory device 150 may include a plurality of NAND strings which extend in the second direction. The plurality of NAND strings may be provided in the first direction and the third direction. Each NAND string may be coupled to a bit line, at least one string select line, at least one ground select line, a plurality of word lines, at least one dummy word line and a common source line, and may include a plurality of transistor structures.

Namely, among the plurality of memory blocks BLK0 to BLKN-1 of the memory device 150, the respective memory blocks BLK0 to BLKN-1 may be coupled to a plurality of bit lines, a plurality of string select lines, a plurality of ground select lines, a plurality of word lines, a plurality of dummy word lines and a plurality of common source lines, and accordingly, may include a plurality of NAND strings. Also, in the respective memory blocks BLK0 to BLKN-1, a plurality of NAND strings may be coupled to one bit line, and a plurality of transistors may be realized in one NAND string. A string select transistor of each NAND string may be coupled to a corresponding bit line, and a ground select transistor of each NAND string may be coupled to the common source line. Memory cells may be provided between the string select transistor and the ground select transistor of each NAND string. Namely, in the plurality of memory blocks BLK0 to BLKN-1 of the memory device 150, a plurality of memory cells may be realized in each of the memory blocks BLK0 to BLKN-1.

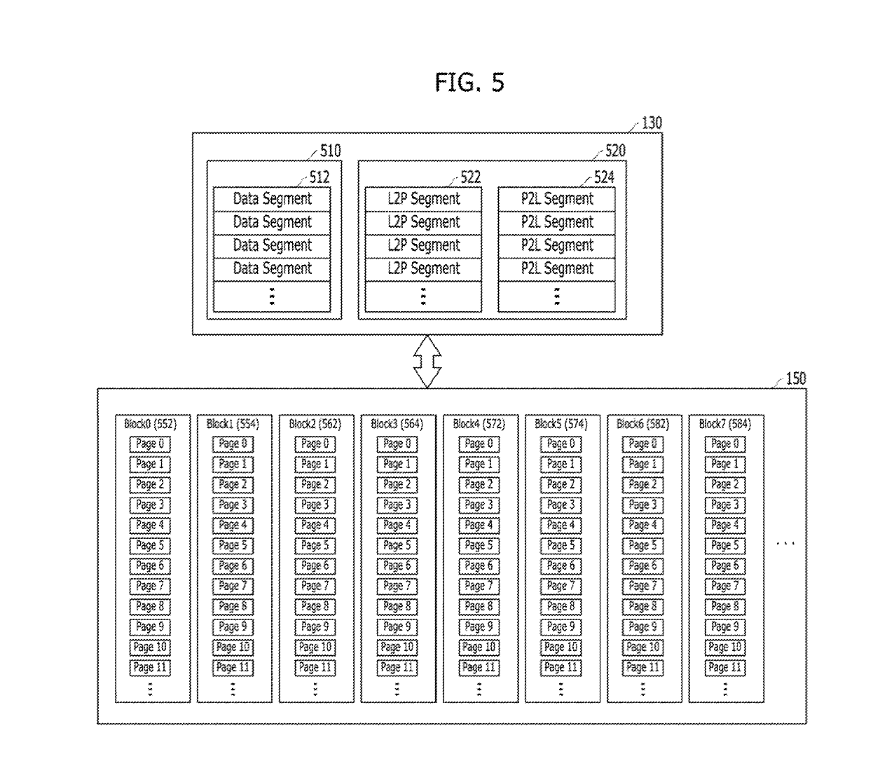

Hereinbelow, detailed descriptions will be made with reference to FIGS. 5 to 7, for a data processing with respect to a memory device 150 in a memory system according to an embodiment of the present invention. Particularly, a command data processing operation corresponding to a command received from the host 102 with respect to the memory device 150 will be described. The command may be a write command also referred to as a program command. In another embodiment the command may be a read command.

FIGS. 5 to 7 are diagrams for illustrating a data processing operation with respect to a memory device in a memory system according to an embodiment of the present invention. The data processing operation may include performing a command operation corresponding to a command received from the host 102 in the memory system 110 shown in FIG. 1. For example, the received command may be a write command, and, hence, the data processing operation may include performing a program operation corresponding to the received write command from the host 102. Or the received command may be a read command, and, hence, the data processing operation may include performing a read operation corresponding to the received read command from the host 102.

In the case where a write command is received form the host 102, the data processing operation may include storing write data corresponding to the received write command, in a first buffer/cache included in the memory 144 of the controller 130. The data processing operation may further include programing and storing the data stored in the buffer/cache of the memory 144 of the controller 130 in at least one first memory block of the memory blocks included in the memory device 150, for example, in a plurality of the memory blocks included in the memory device 150. The write data may include user data and metadata for the user data. The data processing operation may further include generating and updating metadata relating to the stored data in the memory device 150 while the write data are stored in the at least one first memory block of the memory device 150. The metadata may be stored first in a second buffer/cache of the memory 144 of the controller 130. After the metadata are updated based on the latest stored user data in the memory device, the controller may then store the updated metadata in at least one second memory block of the memory blocks of the memory device 150. The at least one first and second memory blocks may be the same blocks or may be different blocks. The at least one first and or second memory blocks may be a superblock comprising a plurality of memory blocks.

In the case where a read command is received for the host 102, the data processing operation may include reading read data from the memory device 150, corresponding to the received read command, storing the read data in a first buffer/cache included in the memory 144 of the controller 130, and providing the data stored in the buffer/cache to the host 102.

In the case of receiving an erase command form the host 102, the data processing operation may include performing an erase operation or a parameter set operation for the memory device 150, to perform the program operation or the read operation for the memory device 150 as described above, or performing a background operation for the memory device 150. In an embodiment of the present disclosure, as a background operation, an operation of copying the data stored in the memory blocks of the memory device 150, to optional memory blocks, for example, a garbage collection (GC) operation, may be performed, an operation of swapping the memory blocks of the memory device 150 or the data stored in the memory blocks, for example, a wear leveling (WL) operation, may be performed, an operation of storing the map data stored in the controller 130, in the memory blocks of the memory device 150, for example, a map flush operation, may be performed, or a bad block management operation of checking and processing a bad block included in the memory device 150 may be performed. Moreover, in an embodiment of the present disclosure, a foreground operation may be performed as a command operation corresponding to a command received from the host 102. For example, a program operation corresponding to a write command, a read operation corresponding to a read command, an erase operation corresponding to an erase command, a parameter set operation corresponding to a set parameter command or a set feature command as a set command, and so forth, may be performed.

That is to say, in an embodiment of the present disclosure, detailed descriptions will be made, as an example, for data processing in the case of performing a foreground operation or a background operation for the memory device 150. In an embodiment of the present disclosure, in the case of performing a foreground operation or a background operation for the memory device 150, in correspondence to performing the foreground operation and the background operation, parameters for the memory device 150 are updated. In particular, operation parameters according to performing the foreground operation and the background operation and state parameters of the memory device 150 when performing the foreground operation and the background operation may be updated.

For example, in an embodiment of the present disclosure, as the foreground operation or the background operation is performed for the memory device 150, as operation parameters for the memory device 150, a write count or a program count, an erase count, a read count, a program/erase cycle or an erase/write cycle, a program voltage offset parameter, an erase voltage offset parameter, a read voltage offset parameter, a read reclaim parameter, an error correction parameter, and so forth, for the plurality of memory blocks included in the memory device 150, may be updated. The write count, the program count or the program voltage offset parameter may be updated in correspondence to a program operation for the respective memory blocks included in the memory device 150. The erase count or the erase voltage offset parameter may be updated in correspondence to an erase operation for the respective memory blocks included in the memory device 150. The program/erase cycle or the erase/write cycle may be updated in correspondence to a program operation and an erase operation for the respective memory blocks included in the memory device 150. In addition, the read count or the read voltage offset parameter may be updated in correspondence to a read operation for the respective memory blocks included in the memory device 150. In particular, the read reclaim parameter may be updated in correspondence to a read reclaim operation for read fail data in a read operation. The error correction parameter may be updated in correspondence to an error correction operation for read fail data in a read operation.

In an embodiment of the present disclosure, when performing a foreground operation or a background operation for the memory device 150, as state parameters for the memory device 150, a temperature parameter, a time parameter, a characteristic parameter, and so forth, for the plurality of memory blocks included in the memory device 150, may be updated. The temperature parameter may be updated in correspondence to temperatures of the respective memory blocks in the case of performing a foreground operation or a background operation for the respective memory blocks included in the memory device 150. In an embodiment of the present disclosure, in the case of performing a foreground operation or a background operation, in particular, performing a read operation, for the respective memory blocks, by considering the temperature parameter, the read operation may be performed by regulating a read voltage. Besides, the time parameter may be updated in correspondence to retention times for the plurality of memory blocks included in the memory device 150. In particular, the time parameter may be updated in correspondence to data storage retention times through a program operation in the plurality of memory cells forming the plurality of pages included in the respective memory blocks. In an embodiment of the present disclosure, in the case of performing a foreground operation or a background operation, in particular, performing a read operation, for the respective memory blocks, by considering the time parameter, the read operation may be performed by regulating a read voltage. The characteristic parameter may be determined in correspondence to the structural characteristics or the operational characteristics of the respective memory blocks in the case of performing a foreground operation or a background operation for the plurality of memory blocks included in the memory device 150. In an embodiment of the present disclosure, in the case of performing a foreground operation or a background operation, in particular, performing a program operation, a read operation or an erase operation, for the respective memory blocks, by considering the characteristic parameter, the program operation, the read operation or the erase operation may be performed by regulating a program voltage, a read voltage or an erase voltage.

In other words, in an embodiment of the present disclosure, in the case of performing a foreground operation or a background operation for the memory device 150, parameters for the memory device 150, that is, operation parameters and state parameters, may be updated. In consideration of the operation parameters and the state parameters updated in this way, the foreground operation or the background operation for the memory device 150 may be performed. In the following description, it will be described, as an example, that the controller 130 performs a data processing operation in the memory system 110, that is, a foreground operation or a background operation, and a parameter update operation for the memory device 150. As described above, the processor 134 included in the controller 130 may perform the operations through, for example, a flash translation layer (FTL).

In an embodiment of the present disclosure, as a foreground operation for the memory device 150, the controller 130 may store user data and metadata corresponding to a write command received from the host 102, in a first buffer included in the memory 144 of the controller 130, and write and store the data stored in the buffer, in an optional memory block among the plurality of memory blocks included in the memory device 150, that is, perform a program operation. Further, the controller 130 may read user data and metadata corresponding to a read command received from the host 102, from the plurality of pages included in a corresponding memory block of the memory device 150, store the read data in a second buffer included in the memory 144 of the controller 130, and provide the data stored in the second buffer, to the host 102, that is, perform a read operation. The first and second buffers may be the same or may be different.

The metadata may include first map data including logical/physical (logical to physical; L2P) informations (hereinafter, referred to as ‘logical informations’) and second map data including physical/logical (physical to logical; P2L) informations (hereinafter, referred to as ‘physical informations’), for the data stored in the memory blocks in correspondence to a program operation. Also, the metadata may include an information on command data corresponding to a command received from the host 102, an information on a command operation corresponding to the command, an information on the memory blocks of the memory device 150 for which the command operation is to be performed, and an information on map data corresponding to the command operation. Namely, the metadata may include all remaining informations and data excluding the user data corresponding to a command received from the host 102. In particular, as described above, not only parameters in the case where the controller 130 performs a foreground operation or a background operation for the memory device 150 but also updated parameters may be included in the metadata.

In an embodiment of the present disclosure, in a case where the controller 130 performs a program operation as a foreground operation, the controller 130 may write and store user data corresponding to a write command received from the host 102, in at least one first memory block of the memory device 150. The at least one first memory block may be an open or a free memory block, among the memory blocks of the memory device 150. Metadata may include mapping informations between logical addresses and physical addresses for the user data stored in the memory blocks, that is, first map data including an L2P map table or an L2P map list in which logical informations are recorded, and mapping informations between physical addresses and logical addresses for the memory blocks in which the user data are stored, that is, second map data including a P2L map table or a P2L map list in which physical informations are recorded. The metadata may be written and stored in at least one second memory block of the memory blocks of the memory device 150. The at least one second memory block may be an open or a free memory block among the memory blocks of the memory device 150. The at least one first and second memory blocks may be the same or different.

In an embodiment, when a write command is received from the host 102, the controller 130 may write and store user data corresponding to the write command, in a plurality of memory blocks, and store metadata including first map data and second map data for the user data stored in the plurality of memory blocks in the same plurality of memory blocks. For example, the controller 130 may store data segments of the user data and meta segments of the metadata for the received user data, e.g., the L2P segments of the first map data and the P2L segments of the second map data as the map segments of map data, in the same memory blocks of the memory device 150. More specifically, the controller 130 may first store the data segments of the user data and the meta segments of the metadata for the user data which are received from the host in the memory 144 included in the controller 130, and then the controller 130 may store the data segments of the user data which are stored in the memory 144 in one or more memory blocks of the memory device 150. As the data segments of the user data are stored in the one or more memory blocks of the memory device 150, the controller 130 may generate meta segments for the user data which are stored in the one or more memory devices of the memory device 150, and update the meta segments which are stored in the memory 144. Then the controller 130 may store the updated meta segments for the user data which are stored in the memory 144 in the same one or more memory blocks of the memory device 150. For example, the controller may perform a map flush operation.

In an embodiment of the present disclosure, in the case where the controller 130 performs a read operation as a foreground operation, the controller 130 may read user data corresponding to a read command received from the host 102, from one or more memory blocks of the memory device 150. In particular, by checking map data for the user data, the controller 130 may read the data stored in one or more pages of a corresponding memory block among the memory blocks of the memory device 150. The controller 130 may store the data read from the memory device 150, in the memory 144 included in the controller 130, and provide the read data to the host 102. In particular, in order to check the map data of the user data corresponding to the read command, the controller 130 may load the map segments of the map data in the memory 144 included in the controller 130, and check the map segments. Hereinbelow, a data processing operation in a memory system according to an embodiment will be described in detail with reference to FIGS. 5 to 7.

First, referring to FIG. 5, in the case of performing a program operation as a foreground operation, the controller 130 may write and store data corresponding to a command received from the host 102, for example, user data corresponding to a write command, in at least one first memory block of the memory blocks 552, 554, 562, 564, 572, 574, 582 and 584 of the memory device 150. Also, in correspondence to the write operation to the at least one first memory block 552, 554, 562, 564, 572, 574, 582 and 584, the controller 130 may generate and update metadata for the user data. The controller 130 may also write and store the metadata in at least one second memory block of the memory blocks 552, 554, 562, 564, 572, 574, 582 and 584 of the memory device 150. The at least one first and second memory blocks may be the same or may be different. The at least one first and second memory blocks may be an open or a free memory block.

The metadata may include first and second map data. The first and second map data may include, information Indicating that the user data are stored in one or more pages included in the least one first memory block of the memory blocks 552, 554, 562, 564, 572, 574, 582 and 584 of the memory device 150. Hence, in an embodiment, for example, the controller 130 may generate and update first and second map data, e.g., informations indicating that the user data are stored in one or more pages included in the at least one first memory block of the memory blocks 552, 554, 562, 564, 572, 574, 582 and 584 of the memory device 150. The first map data may include the logical segments (L2P segments). The second map data may include the physical segments (P2L segments). The controller 130 may then store the L2P segments and the P2L segments in one or more pages included in the at least one second memory block of the memory blocks 552, 554, 562, 564, 572, 574, 582 and 584 of the memory device 150, by performing a map flush operation.

For example, the controller 130 may cache and buffer the user data corresponding to the write command received from the host 102, in a first buffer 510 included in the memory 144 of the controller 130. More specifically, the controller 130 may store the data segments 512 of the user data in the first buffer 510 as a data buffer/cache. Then, the controller 130 may write and store the data segments 512 stored in the first buffer 510, in one or more pages included in the at least one first memory block of the memory blocks 552, 554, 562, 564, 572, 574, 582 and 584 of the memory device 150.

As the data segments 512 of the user data corresponding to the write command received from the host 102 are written and stored in one or more pages included in the at least one first memory block of the memory blocks 552, 554, 562, 564, 572, 574, 582 and 584 of the memory device 150, the controller 130 may generate the first map data and the second map data, and store the first map data and the second map data in a second buffer 520 included in the memory 144 of the controller 130. More specifically, the controller 130 may store L2P segments 522 of the first map data for the user data and P2L segments 524 of the second map data for the user data, in the second buffer 520 as a map buffer/cache. In the second buffer 520 in the memory 144 of the controller 130, there may be stored, as described above, the L2P segments 522 of the first map data and the P2L segments 524 of the second map data, or there may be stored a map list for the L2P segments 522 of the first map data and a map list for the P2L segments 524 of the second map data. The controller 130 may write and store the L2P segments 522 of the first map data and the P2L segments 524 of the second map data which are stored in the second buffer 520, in one or more pages included in the at least one second memory block of the memory blocks 552, 554, 562, 564, 572, 574, 582 and 584 of the memory device 150.

Also, in the case of performing a read operation as a foreground operation, the controller 130 may load the map segments of data corresponding to a command received from the host 102, for example, user data corresponding to a read command, for example, L2P segments 522 of first map data and P2L segments 524 of second map data, in the second buffer 520, and check the L2P segments 522 and the P2L segments 524. After that, the controller 130 may read the user data stored in one or more pages included in at least one corresponding memory block among the memory blocks 552, 554, 562, 564, 572, 574, 582 and 584 of the memory device 150, store data segments 512 of the read user data in the first buffer 510, and provide the data segments 512 to the host 102.

In the case of performing a foreground operation, for example, an erase operation, or performing a background operation, for example, an operation of copying data or swapping data among the memory blocks included in the memory device 150, for example, a garbage collection operation or a wear leveling operation, as described above, the controller 130 may store data segments 512 of corresponding user data, in the first buffer 510, and store the meta segments of corresponding metadata, for example, map segments 522 and 524 of map data, in the second buffer 520, thereby performing the foreground operation or the background operation.

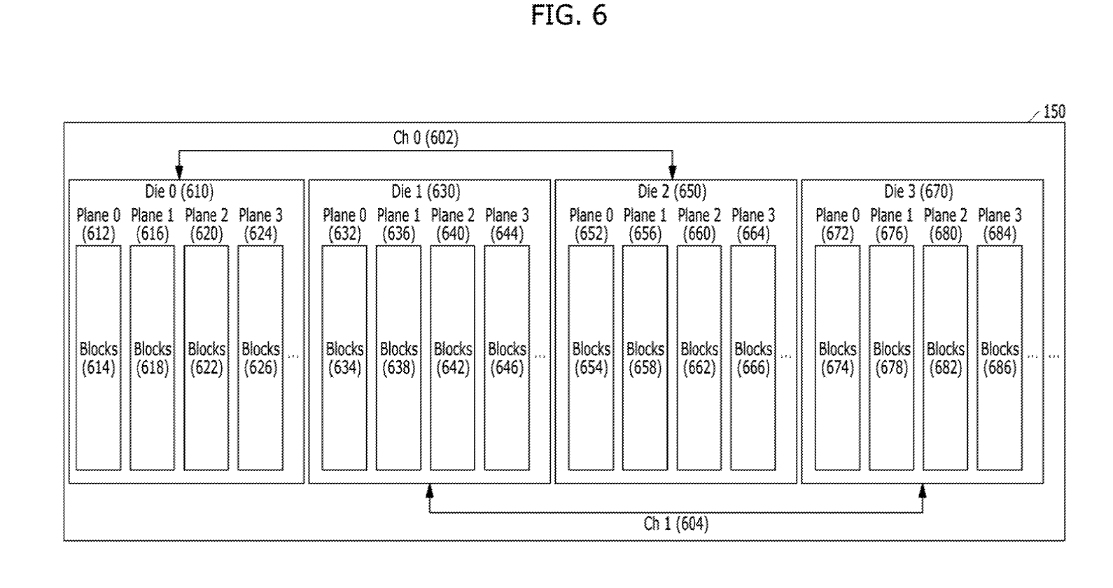

Referring to FIG. 6, the memory device 150 may include a plurality of memory dies, for example, a memory die 0 610, a memory die 1 630, a memory die 2 650 and a memory die 3 670. Each of the memory dies 610, 630, 650 and 670 may include a plurality of planes. For example, the memory die 0 610 may include a plane 0 612, a plane 1 616, a plane 2 620 and a plane 3 624, the memory die 1 630 may include a plane 0 632, a plane 1 636, a plane 2 640 and a plane 3 644, the memory die 2 650 may include a plane 0 652, a plane 1 656, a plane 2 660 and a plane 3 664, and the memory die 3 670 may include a plane 0 672, a plane 1 676, a plane 2 680 and a plane 3 684. The respective planes 612, 616, 620, 624, 632, 636, 640, 644, 652, 656, 660, 664, 672, 676, 680 and 684 in the memory dies 610, 630, 650 and 670 included in the memory device 150 may each include a plurality of memory blocks, 614, 618, 622, 626, 634, 638, 642, 646, 654, 658, 662, 666, 674, 678, 682 and 686, for example, N number of blocks Block0, Block1, . . . and BlockN-1 including a plurality of pages, for example, 2̂M number of pages, as described above with reference to FIG. 2. The plurality of memory dies of the memory device 150 may be coupled to the same channels. For example, the memory die 0 610 and the memory die 2 650 may be coupled to a channel 0 602, and the memory die 1 630 and the memory die 3 670 may be coupled to a channel 1 604.

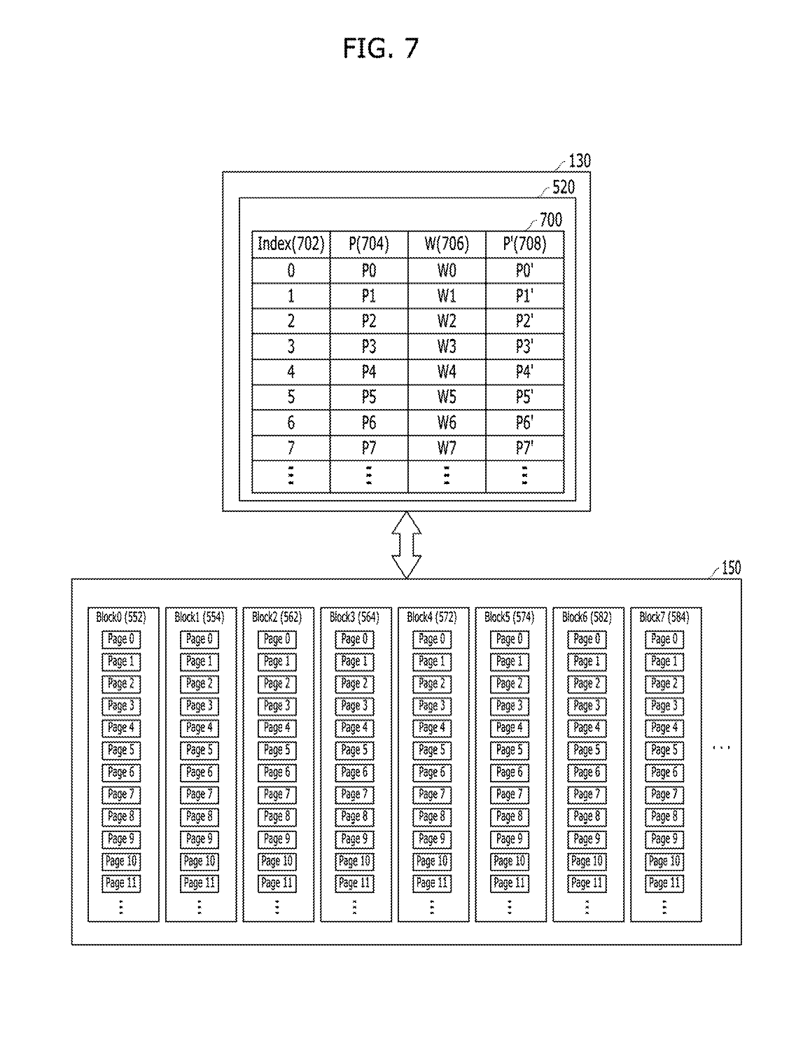

In the embodiment of the present disclosure, the controller 130 may perform a foreground operation or a background operation, as described above, for the memory blocks 614, 618, 622, 626, 634, 638, 642, 646, 654, 658, 662, 666, 674, 678, 682 and 686 of the respective planes 612, 616, 620, 624, 632, 636, 640, 644, 652, 656, 660, 664, 672, 676, 680 and 684 included in the respective memory dies 610, 630, 650 and 670 of the memory device 150. Also, in correspondence to the foreground operation or the background operation, the controller 130 may update parameters for the respective memory blocks 614, 618, 622, 626, 634, 638, 642, 646, 654, 658, 662, 666, 674, 678, 682 and 686, and then, perform a foreground operation or a background operation for the respective memory blocks 614, 618, 622, 626, 634, 638, 642, 646, 654, 658, 662, 666, 674, 678, 682 and 686, by considering the updated parameters. Hereinbelow, detailed descriptions will be made with reference to FIG. 7 by taking an example, for, in the case of performing a foreground operation or a background operation for the memory device 150 in a memory system according to an embodiment, an operation of updating parameters for the memory device 150 and a foreground operation or a background operation for the memory device 150, performed by considering updated parameters.

Referring to FIG. 7, as described above, the memory device 150 may include a plurality of memory dies, each of the memory dies may include a plurality of planes, and each of the planes may include a plurality of memory blocks. The controller 130 may perform a foreground operation or a background operation for one or more of the memory blocks included in the memory device 150. The controller 130 may update one or more parameters for the one or more memory blocks of the memory device 150 in correspondence to the foreground operation or the background operation, and perform the foreground operation or the background operation for the respective memory blocks of the memory device 150, by considering the updated parameters.

In the described embodiment of FIG. 7, descriptions are made by taking an example that the memory block 0 552 and the memory block 1 554 are memory blocks included in the plane 0 612 of the memory die 0 610 in FIG. 6 and are single level cell (SLC) memory blocks, the memory block 2 562 is a memory block included in the plane 0 632 of the memory die 1 630 in FIG. 6 and is a single level cell memory block, and the memory block 3 564 is a memory block included in the plane 1 636 of the memory die 1 630 in FIG. 6 and is a single level cell memory block. Also, in the described embodiment of FIG. 7, descriptions are made by taking an example that the memory block 4 572 is a memory block included in the plane 0 652 of the memory die 2 650 in FIG. 6 and is a multi-level cell (MLC) memory block, the memory block 5 574 is a memory block included in the plane 1 656 of the memory die 2 650 and is a multi-level cell memory block, the memory block 6 582 is a memory block included in the plane 0 672 of the memory die 3 670 and is a triple level cell (TLC) memory block, and the memory block 7 584 is a memory block included in the plane 1 676 of the memory die 3 670 and is a triple level cell memory block.

In the memory system according to the described embodiment, as described above, the controller 130 may perform a foreground operation, for example, a program operation, a read operation, an erase operation, a parameter set operation, and so forth, or perform a background operation, for example, a garbage collection operation, a wear leveling operation, a map flush operation, a bad block management operation, and so forth, for the memory blocks 552, 554, 562, 564, 572, 574, 582 and 584 of the memory device 150. The controller 130 may update parameters for the memory blocks 552, 554, 562, 564, 572, 574, 582 and 584 of the memory device 150, for example, operation parameters and state parameters for the respective memory blocks 552, 554, 562, 564, 572, 574, 582 and 584, in correspondence to performing the foreground operation or the background operation, and perform a foreground operation or a background operation for the respective memory blocks 552, 554, 562, 564, 572, 574, 582 and 584, by considering the updated operation parameters and state parameters.

In detail, the controller 130 may perform a foreground operation or a background operation for the memory blocks 552, 554, 562, 564, 572, 574, 582 and 584, and, in correspondence to the foreground operation or the background operation, generate a parameter list 700 in which parameters for the respective memory blocks 552, 554, 562, 564, 572, 574, 582 and 584 are recorded.

The controller 130 may record parameters for the respective memory blocks 552, 554, 562, 564, 572, 574, 582 and 584, in the parameter list 700, and store the parameter list 700 in the second buffer 520 included in the memory 144 of the controller 130. Since parameters for the respective memory blocks 552, 554, 562, 564, 572, 574, 582 and 584 may be included in metadata as described above, the parameter list 700 may be stored in the memory device 150 by being included in the metadata.

In particular, the controller 130 may record, in the parameter list 700, parameters 704 corresponding to performing a foreground operation or a background operation in the respective memory blocks 552, 554, 562, 564, 572, 574, 582 and 584, by indexes 702 indicating the memory blocks 552, 554, 562, 564, 572, 574, 582 and 584 of the memory device 150. The parameters 704 recorded in the parameter list 700 by the memory blocks 552, 554, 562, 564, 572, 574, 582 and 584 may include operation parameters and state parameters in the respective memory blocks 552, 554, 562, 564, 572, 574, 582 and 584, as described above.

The controller 130 may normalize the parameters 704 of the respective memory blocks 552, 554, 562, 564, 572, 574, 582 and 584 recorded in the parameter list 700, and record normalized parameters 708 for the respective memory blocks 552, 554, 562, 564, 572, 574, 582 and 584, in the parameter list 700 by the indexes 702. The controller 130 may normalize the parameters 704 of the respective memory blocks 552, 554, 562, 564, 572, 574, 582 and 584 by granting weights 706 set by the respective memory blocks 552, 554, 562, 564, 572, 574, 582 and 584, to the parameters 704 of the respective memory blocks 552, 554, 562, 564, 572, 574, 582 and 584, and record the normalized parameters 708 of the respective memory blocks 552, 554, 562, 564, 572, 574, 582 and 584 in the parameter list 700.

When making detailed descriptions by taking an example, the controller 130 may set the weights 706 by the respective memory blocks 552, 554, 562, 564, 572, 574, 582 and 584, in correspondence to the operational characteristics and the structural characteristics of the respective memory blocks 552, 554, 562, 564, 572, 574, 582 and 584. In particular, the controller 130 may set the weights 706 by the respective memory blocks 552, 554, 562, 564, 572, 574, 582 and 584 in correspondence to the memory cell types of the respective memory blocks 552, 554, 562, 564, 572, 574, 582 and 584. In other words, the controller 130 may set weights of respectively different magnitudes in correspondence to memory cell types in the respective memory blocks 552, 554, 562, 564, 572, 574, 582 and 584, for example, single level cell memory blocks, multi-level cell memory blocks and triple level cell memory blocks. For instance, in the case of performing a foreground operation or a background operation for the respective memory blocks 552, 554, 562, 564, 572, 574, 582 and 584, a stress level for memory cells in a single level cell memory block (hereinafter, referred to as a ‘first stress level’), a stress level for memory cells in a multi-level cell memory block (hereinafter, referred to as a ‘second stress level’) and a stress level for memory cells in a triple level cell memory block (hereinafter, referred to as a ‘third stress level’) may be different from one another. Therefore, the controller 130 may set respective weights corresponding to the respective memory blocks 552, 554, 562, 564, 572, 574, 582 and 584, by considering stress levels in the respective memory blocks 552, 554, 562, 564, 572, 574, 582 and 584.

In the case where the controller 130 performs a foreground operation or a background operation for the respective memory blocks 552, 554, 562, 564, 572, 574, 582 and 584 according to respective stress levels, operational characteristic degradation may occur in the memory cells included in the respective memory blocks 552, 554, 562, 564, 572, 574, 582 and 584. In particular, since the first stress level is a lowest level and the third stress level is a highest level, characteristic degradation in the memory blocks corresponding to the first stress level may be smallest, and characteristic degradation in the memory blocks corresponding to the third stress level may be largest.

Namely, in the case of performing a foreground operation or a background operation, since stress levels in the respective memory blocks 552, 554, 562, 564, 572, 574, 582 and 584 are different due to the operational characteristics and the structural characteristics of the respective memory blocks 552, 554, 562, 564, 572, 574, 582 and 584, the controller 130 may set the respective weights 706 corresponding to the respective memory blocks 552, 554, 562, 564, 572, 574, 582 and 584, in correspondence to the operational characteristic degradation in the respective memory blocks 552, 554, 562, 564, 572, 574, 582 and 584 according to the respective stress levels. For example, the controller 130 may set a weight of a first magnitude to memory blocks corresponding to the first stress level, set a weight of a second magnitude to memory blocks corresponding to the second stress level, and set a weight of a third magnitude to memory blocks corresponding to the third stress level. The weight of the first magnitude may be a weight of a largest magnitude, and the weight of the third magnitude may be a weight of a smallest magnitude.

For instance, the controller 130 may set the weight 706 of the memory block 0 552 as “W0” in correspondence to the stress level of the memory block 0 552 in the case of performing a foreground operation or a background operation in the memory block 0 552, set the weight 706 of the memory block 1 554 as “W1” in correspondence to the stress level of the memory block 1 554 in the case of performing a foreground operation or a background operation in the memory block 1 554, set the weight 706 of the memory block 2 562 as “W2” in correspondence to the stress level of the memory block 2 562 in the case of performing a foreground operation or a background operation in the memory block 2 562, and set the weight 706 of the memory block 3 564 as “W3” In correspondence to the stress level of the memory block 3 564 in the case of performing a foreground operation or a background operation in the memory block 3 564. Further, the controller 130 may set the weight 706 of the memory block 4 572 as “W4” in correspondence to the stress level of the memory block 4 572 in the case of performing a foreground operation or a background operation in the memory block 4 572, set the weight 706 of the memory block 5 574 as “W5” in correspondence to the stress level of the memory block 5 574 in the case of performing a foreground operation or a background operation in the memory block 5 574, set the weight 706 of the memory block 6 582 as “W6” in correspondence to the stress level of the memory block 6 582 in the case of performing a foreground operation or a background operation in the memory block 6 582, and set the weight 706 of the memory block 7 584 as “W7” in correspondence to the stress level of the memory block 7 584 in the case of performing a foreground operation or a background operation in the memory block 7 584.

The controller 130 may record the weights 706 respectively set for the respective memory blocks 552, 554, 562, 564, 572, 574, 582 and 584, in the parameter list 700. For example, in the parameter list 700, the weight 706 of “W0” is recorded in correspondence to the index 702 of “0” of the memory block 0 552, the weight 706 of “W1” is recorded in correspondence to the index 702 of “1” of the memory block 1 554, the weight 706 of “W2” is recorded in correspondence to the index 702 of “2” of the memory block 2 562, the weight 706 of “W3” is recorded in correspondence to the index 702 of “3” of the memory block 3 564, the weight 706 of “W4” is recorded in correspondence to the index 702 of “4” of the memory block 4 572, the weight 706 of “W5” is recorded in correspondence to the index 702 of “5” of the memory block 5 574, the weight 706 of “W6” is recorded in correspondence to the index 702 of “6” of the memory block 6 582, and the weight 706 of “W7” is recorded in correspondence to the index 702 of “7” of the memory block 7 584.

The controller 130 may record, as described above, the parameter 704 of “P0” of the memory block 0 552 in the case of performing a foreground operation or a background operation in the memory block 0 552, in correspondence to the index 702 of “0” of the memory block 0 552 in the parameter list 700, and record the parameter 704 of “P1” of the memory block 1 554 in the case of performing a foreground operation or a background operation in the memory block 1 554, in correspondence to the index 702 of “1” of the memory block 1 554 in the parameter list 700. The controller 130 may record the parameter 704 of “P2” of the memory block 2 562 in the case of performing a foreground operation or a background operation in the memory block 2 562, in correspondence to the index 702 of “2” of the memory block 2 562 in the parameter list 700, and record the parameter 704 of “P3” of the memory block 3 564 in the case of performing a foreground operation or a background operation in the memory block 3 564, in correspondence to the index 702 of “3” of the memory block 3 564 in the parameter list 700. The controller 130 may record the parameter 704 of “P4” of the memory block 4 572 in the case of performing a foreground operation or a background operation in the memory block 4 572, in correspondence to the index 702 of “4” of the memory block 4 572 in the parameter list 700, and record the parameter 704 of “P5” of the memory block 5 574 in the case of performing a foreground operation or a background operation in the memory block 5 574, in correspondence to the index 702 of “5” of the memory block 5 574 in the parameter list 700. The controller 130 may record the parameter 704 of “P6” of the memory block 6 582 in the case of performing a foreground operation or a background operation in the memory block 6 582, in correspondence to the index 702 of “6” of the memory block 6 582 in the parameter list 700, and record the parameter 704 of “P7” of the memory block 7 584 in the case of performing a foreground operation or a background operation in the memory block 7 584, in correspondence to the index 702 of “7” of the memory block 7 584 in the parameter list 700.

The parameters 704 of the respective memory blocks 552, 554, 562, 564, 572, 574, 582 and 584 recorded in the parameter list 700 may include operation parameters for the respective memory blocks 552, 554, 562, 564, 572, 574, 582 and 584, for example, write counts, program counts, erase counts, read counts, program/erase cycles, erase/write cycles, program voltage offset parameters, erase voltage offset parameters, read voltage offset parameters, read reclaim parameters, error correction parameters, and so forth, and state parameters for the respective memory blocks 552, 554, 562, 564, 572, 574, 582 and 584, for example, temperature parameters, time parameters, characteristic parameters, and so forth.

In the case of performing a foreground operation or a background operation in the respective memory blocks 552, 554, 562, 564, 572, 574, 582 and 584, by granting the respective weights 706 set by the respective memory blocks 552, 554, 562, 564, 572, 574, 582 and 584, to the parameters 704 of the respective memory blocks 552, 554, 562, 564, 572, 574, 582 and 584, the controller 130 may normalize the parameters 704 of the respective memory blocks 552, 554, 562, 564, 572, 574, 582 and 584, that is, generate the normalized parameters 708 for the respective memory blocks 552, 554, 562, 564, 572, 574, 582 and 584. The normalized parameters 708 of the respective memory blocks 552, 554, 562, 564, 572, 574, 582 and 584 may be recorded in the parameter list 700 by the Indexes 702 of the respective memory blocks 552, 554, 562, 564, 572, 574, 582 and 584, as described above.

In the case of performing a foreground operation or a background operation for the respective memory blocks 552, 554, 562, 564, 572, 574, 582 and 584, the controller 130 may perform the foreground operation or the background operation by using the normalized parameters 708 of the respective memory blocks 552, 554, 562, 564, 572, 574, 582 and 584 recorded in the parameter list 700. After performing a foreground operation or a background operation for the respective memory blocks 552, 554, 562, 564, 572, 574, 582 and 584, through the normalized parameters 708, the controller 130 may update the parameters 704 of the respective memory blocks 552, 554, 562, 564, 572, 574, 582 and 584 recorded in the parameter list 700. By granting the weights 706 to the updated parameters 704 of the respective memory blocks 552, 554, 562, 564, 572, 574, 582 and 584, the controller 130 may normalize again the updated parameters 704 of the respective memory blocks 552, 554, 562, 564, 572, 574, 582 and 584, that is, generate again the normalized parameters 708 for the updated parameters 704. By recording the normalized parameters 708 in the parameter list 700, the controller 130 may update the parameter list 700.

That is to say, the controller 130 may update the parameters 704 and the normalized parameters 708 of the respective memory blocks 552, 554, 562, 564, 572, 574, 582 and 584 recorded in the parameter list 700, in correspondence to performing a foreground operation or a background operation in the respective memory blocks 552, 554, 562, 564, 572, 574, 582 and 584, and perform a foreground operation or a background operation through the normalized parameters 708 of the respective memory blocks 552, 554, 562, 564, 572, 574, 582 and 584. Hereinbelow, detailed descriptions will be made by taking, as an example, the case of performing a foreground operation, for example, a read operation, in the memory block 0 552 as a single level cell memory block, the memory block 4 572 as a multi-level cell memory block and the memory block 6 582 as a triple level cell memory block.

First, in the case of performing a read operation for the memory block 0 552, the memory block 4 572 and the memory block 6 582 in correspondence to a read command received from the host 102, the controller 130 may check the parameters 704, for example, read voltage offset parameters, for the memory block 0 552, the memory block 4 572 and the memory block 6 582, and record the parameters 704 in the parameter list 700. For the sake of convenience in explanation, descriptions will be made by taking an example that the read voltage offset parameters of the memory block 0 552, the memory block 4 572 and the memory block 6 582 are all the same.

In other words, in the parameter list 700, there may be recorded the read voltage offset parameter “P0=10” of the memory block 0 552, the read voltage offset parameter “P4=10” of the memory block 4 572 and the read voltage offset parameter “P6=10” of the memory block 6 582. The weights 706 may be set to the memory block 0 552, the memory block 4 572 and the memory block 6 582, respectively, in correspondence to the stress levels thereof. For example, the weight “W0=10” of the memory block 0 552 in correspondence to the first stress level may be set to the memory block 0 552, the weight “W4=20” of the memory block 4 572 in correspondence to the second stress level may be set to the memory block 4 572, and the weight “W6=30” of the memory block 6 582 in correspondence to the third stress level may be set to the memory block 6 582.

Therefore, by granting respectively the weights of the memory block 0 552, the memory block 4 572 and the memory block 6 582 to the read voltage offset parameters of the memory block 0 552, the memory block 4 572 and the memory block 6 582, the controller 130 may normalize the read voltage offset parameters of the memory block 0 552, the memory block 4 572 and the memory block 6 582, that is, generate the normalized read voltage offset parameters of the memory block 0 552, the memory block 4 572 and the memory block 6 582. The controller 130 may generate the normalized read voltage offset parameter “P0′=10” of the memory block 0 552, the normalized read voltage offset parameter “P4′=200” of the memory block 4 572 and the normalized read voltage offset parameter “P6′=300” of the memory block 6 582.

In the case of performing the read operation for the memory block 0 552, the memory block 4 572 and the memory block 6 582 in correspondence to the read command received from the host 102, the controller 130 may perform the read operation for the memory block 0 552, the memory block 4 572 and the memory block 6 582, by using the normalized read voltage offset parameters of the memory block 0 552, the memory block 4 572 and the memory block 6 582. For example, the controller 130 may perform the read operation for the memory block 0 552 through the normalized read voltage offset parameter “P0′=100” of the memory block 0 552, for instance, perform the read operation for the memory block 0 552 by using the voltage offset of 100 with respect to the reference read voltage of the memory device 150. The controller 130 may perform the read operation for the memory block 4 572 through the normalized read voltage offset parameter “P4′=200” of the memory block 4 572, for instance, perform the read operation for the memory block 4 572 by using the voltage offset of 200 with respect to the reference read voltage of the memory device 150. The controller 130 may perform the read operation for the memory block 6 582 through the normalized read voltage offset parameter “P6′=300” of the memory block 6 582, for instance, perform the read operation for the memory block 6 582 by using the voltage offset of 300 with respect to the reference read voltage of the memory device 150.

After performing, as described above, the read operation for the memory block 0 552, the memory block 4 572 and the memory block 6 582, by using the normalized read voltage offset parameters of the memory block 0 552, the memory block 4 572 and the memory block 6 582, the controller 130 may update the read voltage offset parameters of the memory block 0 552, the memory block 4 572 and the memory block 6 582, and, by granting weights to the read voltage offset parameters of the memory block 0 552, the memory block 4 572 and the memory block 6 582, update the normalized read voltage offset parameters.

Hereinbelow, detailed descriptions will be made by taking, as an example, the case of performing a background operation, for example, a wear leveling operation, in the memory block 0 552, the memory block 1 554, the memory block 2 562 and the memory block 3 564 as single level cell memory blocks.

First, in the case of performing an erase operation for the memory block 0 552, the memory block 1 554, the memory block 2 562 and the memory block 3 564 in correspondence to an erase command received from the host 102, the controller 130 may check the parameters 704, for example, erase counts, for the memory block 0 552, the memory block 1 554, the memory block 2 562 and the memory block 3 564, and record the parameters 704 in the parameter list 700.

Namely, in the parameter list 700, there may be recorded the erase count “P0=200” of the memory block 0 552, the erase count “P1=250” of the memory block 1 554, the erase count “P2=150” of the memory block 2 562 and the erase count “P3=200” of the memory block 3 564. The weights 706 may be set to the memory block 0 552, the memory block 1 554, the memory block 2 562 and the memory block 3 564, respectively, in correspondence to the stress levels thereof. For example, the weight “W0=10” of the memory block 0 552 in correspondence to the stress level of the memory block 0 552 may be set to the memory block 0 552, the weight “W1=20” of the memory block 1 554 in correspondence to the stress level of the memory block 1 554 may be set to the memory block 1 554, the weight “W2=30” of the memory block 2 562 in correspondence to the stress level of the memory block 2 562 may be set to the memory block 2 562, and the weight “W3=40” of the memory block 4 564 in correspondence to the stress level of the memory block 4 564 may be set to the memory block 4 564.

Therefore, by granting respectively the weights of the memory block 0 552, the memory block 1 554, the memory block 2 562 and the memory block 3 564 to the erase counts of the memory block 0 552, the memory block 1 554, the memory block 2 562 and the memory block 3 564, the controller 130 may normalize the erase counts of the memory block 0 552, the memory block 1 554, the memory block 2 562 and the memory block 3 564, that is, generate the normalized erase counts of the memory block 0 552, the memory block 1 554, the memory block 2 562 and the memory block 3 564. The controller 130 may generate the normalized erase count “P0′=2000” of the memory block 0 552, the normalized erase count “P1′=5000” of the memory block 1 554, the normalized erase count “P2′=4500” of the memory block 2 562 and the normalized erase count “P3′=8000” of the memory block 3 564.

In the case of performing the wear leveling operation for the memory block 0 552, the memory block 1 554, the memory block 2 562 and the memory block 3 564, the controller 130 may perform the erase operation for the memory block 0 552, the memory block 1 554, the memory block 2 562 and the memory block 3 564, by using the normalized erase counts of the memory block 0 552, the memory block 1 554, the memory block 2 562 and the memory block 3 564. For example, through the normalized erase counts of the memory block 0 552, the memory block 1 554, the memory block 2 562 and the memory block 3 564, the controller 130 may perform the wear leveling operation by selecting the memory block 3 564 as a source memory block, selecting the memory block 0 552 as a target memory block and swapping between the memory block 3 564 and the memory block 0 552.

After performing, as described above, the wear leveling operation for the memory block 0 552, the memory block 1 554, the memory block 2 562 and the memory block 3 564, by using the normalized erase counts of the memory block 0 552, the memory block 1 554, the memory block 2 562 and the memory block 3 564, the controller 130 may update the erase counts of the memory block 0 552, the memory block 1 554, the memory block 2 562 and the memory block 3 564, and, by granting weights to the erase counts of the memory block 0 552, the memory block 1 554, the memory block 2 562 and the memory block 3 564, update normalized erase counts.

In the case of copying and storing the data stored in an optional memory block to and in another optional memory block, as a background operation in the memory blocks 552, 554, 562, 564, 572, 574, 582 and 584, the controller 130 may select a first memory block as a source memory block and a second memory block as a target memory block among the memory blocks 552, 554, 562, 564, 572, 574, 582 and 584, by using the normalized parameters 708 in the respective memory blocks 552, 554, 562, 564, 572, 574, 582 and 584, as described above, and then, copy and store the data stored one or more pages of the first memory block, to and one or more pages of the second memory block. After performing the copy operation as described above, the controller 130 may update the parameters 704 of the respective memory blocks 552, 554, 562, 564, 572, 574, 582 and 584, and generate the normalized parameters 708 for the respective memory blocks 552, 554, 562, 564, 572, 574, 582 and 584 of which parameters 704 are updated, that is, update the normalized parameters 708 of the respective memory blocks 552, 554, 562, 564, 572, 574, 582 and 584.

In this way, in the memory system according to an embodiment of the present disclosure, in the case of performing a foreground operation or a background operation for the memory device 150, the parameters of the memory device 150 may be checked in correspondence to the performing the foreground operation or the background operation. Also, the normalized parameters of the memory device 150 may be generated by granting weights to the parameters of the memory device 150, and a foreground operation or a background operation for the memory device 150 may be performed by using the normalized parameters of the memory device 150. As a result, in the memory system according to an embodiment of the present disclosure, in the case of performing a foreground operation or a background operation for the memory device 150, the foreground operation or the background operation may be performed by considering operational characteristic degradation according to stress levels in the memory device 150, and accordingly, the operational performance and reliability of the memory device 150 may be improved.

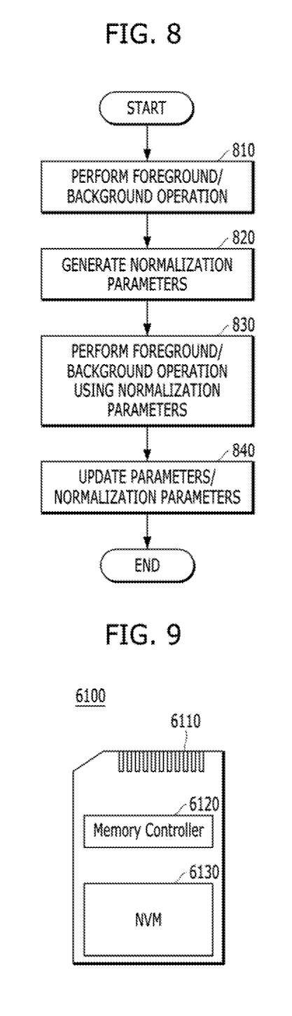

Hereinbelow, an operation for processing data in a memory system according to an embodiment will be described in detail with reference to FIG. 8.

FIG. 8 is a flow chart of an operation process for processing data in a memory system according to an embodiment.

Referring to FIG. 8, at step 810, the memory system may perform a foreground operation or a background operation for one or more of the memory blocks included in the memory device 150. The foreground operation may include a command operation corresponding to a command received from the host 102. For example, the foreground operation may include a program operation corresponding to a write command, a read operation corresponding to a read command, an erase operation corresponding to an erase command, a parameter set operation corresponding to a set command, and so forth. The background operation may include an operation of copying data or an operation of swapping data in the memory blocks of the memory device 150. For example, the background operation may include a garbage collection operation or a wear leveling operation, a map flush operation, a bad block management operation, and so forth.

At step 820, normalized parameters may be generated for the respective one or more memory blocks for which the foreground operation or the background operation is to be performed. More specifically, parameters may be checked for the one or more memory blocks, and, by employing weights set for the respective one or more memory blocks, the parameters of the respective one or more memory blocks may be normalized. As aforementioned, the weights for the respective memory blocks may be determined in correspondence to stress levels in the respective memory blocks in the case of performing the foreground operation or the background operation in the respective memory blocks. For instance, since the stress levels in the respective memory blocks are different in correspondence to the memory cell types of the respective memory blocks, the weights may be set having different magnitudes according to the stress levels in the respective memory blocks.

At step 830, by using the normalized parameters of the respective memory blocks, a foreground operation or a background operation may be performed in the respective memory blocks.

At step 840, the parameters and the normalized parameters are updated. More specifically, after updating the parameters for the respective memory blocks for which the foreground operation or the background operation is performed, the updated parameters of the respective memory blocks may be normalized, that is the normalized parameters in the respective memory blocks may be updated.

Since detailed descriptions were made above with reference to FIGS. 5 to 7, for performing the foreground operation or the background operation for the respective memory blocks included in the memory device of the memory system, checking the parameters and setting weights of the parameters of the respective memory blocks in correspondence to performing the foreground operation or the background operation, normalizing the parameters of the respective memory blocks, that is, generating normalized parameters, performing a foreground operation or a background operation in the respective memory blocks by using the normalized parameters, and updating the parameters and the normalized parameters of the respective memory blocks, further descriptions thereof will be omitted herein.

FIGS. 9 to 14 are diagrams illustrating memory systems according to various embodiments of the present invention.

FIG. 9 is a diagram illustrating a memory card system 6100 as the data processing system described above with reference to FIGS. 1 to 8.

Referring to FIG. 9, the memory card system 6100 includes a memory controller 6120, a memory device 6130, and a connector 6110.

In detail, the memory controller 6120 may be connected with the memory device 6130 and may access the memory device 6130. In some embodiments, the memory device 6130 may be implemented with a nonvolatile memory (NVM). The memory controller 6120 may control read, write, erase and background operations for the memory device 6130. The memory controller 6120 may provide an interface between the memory device 6130 and a host (not shown), and may drive a firmware for controlling the memory device 6130. For example, the memory controller 6120 may correspond to the controller 130 in the memory system 110 described above with reference to FIG. 1, and the memory device 6130 may correspond to the memory device 150 in the memory system 110 described above with reference to FIG. 1.

Therefore, the memory controller 6120 may include components such as a random access memory (RAM), a processing unit, a host interface, a memory interface and an error correction unit as shown in FIG. 1.

The memory controller 6120 may communicate with an external device (for example, the host 102 described above with reference to FIG. 1), through the connector 6110. For example, as described above with reference to FIG. 1, the memory controller 6120 may be configured to communicate with the external device through at least one of various communication protocols such as a universal serial bus (USB), multimedia card (MMC), an embedded MMC (eMMC), a peripheral component interconnection (PCI), a PCI express (PCIe), an advanced technology attachment (ATA), a serial-ATA, a parallel-ATA, a small computer system interface (SCSI), enhanced small disk interface (ESDI), an integrated drive electronics (IDE), a firewire, a universal flash storage (UFS), a wireless-fidelity (WI-FI) and a bluetooth. Accordingly, the memory system and the data processing system according to the embodiment may be applied to wired/wireless electronic appliances, for example, a mobile electronic appliance.

The memory device 6130 may be implemented with a nonvolatile memory. For example, the memory device 6130 may be implemented with various nonvolatile semiconductor memory devices such as an electrically erasable and programmable ROM (EPROM), a NAND flash memory, a NOR flash memory, a phase-change RAM (PRAM), a resistive RAM (ReRAM), a ferroelectric RAM (FRAM) and a spin torque transfer magnetic RAM (STT-MRAM).

The memory controller 6120 and the memory device 6130 may be integrated into a single semiconductor device. For example, the memory controller 6120 and the memory device 6130 may construct a solid state driver (SSD) by being integrated into a single semiconductor device. The memory controller 6120 and the memory device 6130 may construct a memory card such as a PC card (PCMCIA: Personal Computer Memory Card International Association), a compact flash card (CF), a smart media card (SM and SMC), a memory stick, a multimedia card (MMC, RS-MMC, MMCmicro and eMMC), an SD card (e.g., SD, miniSD, microSD and SDHC) and a universal flash storage (UFS).

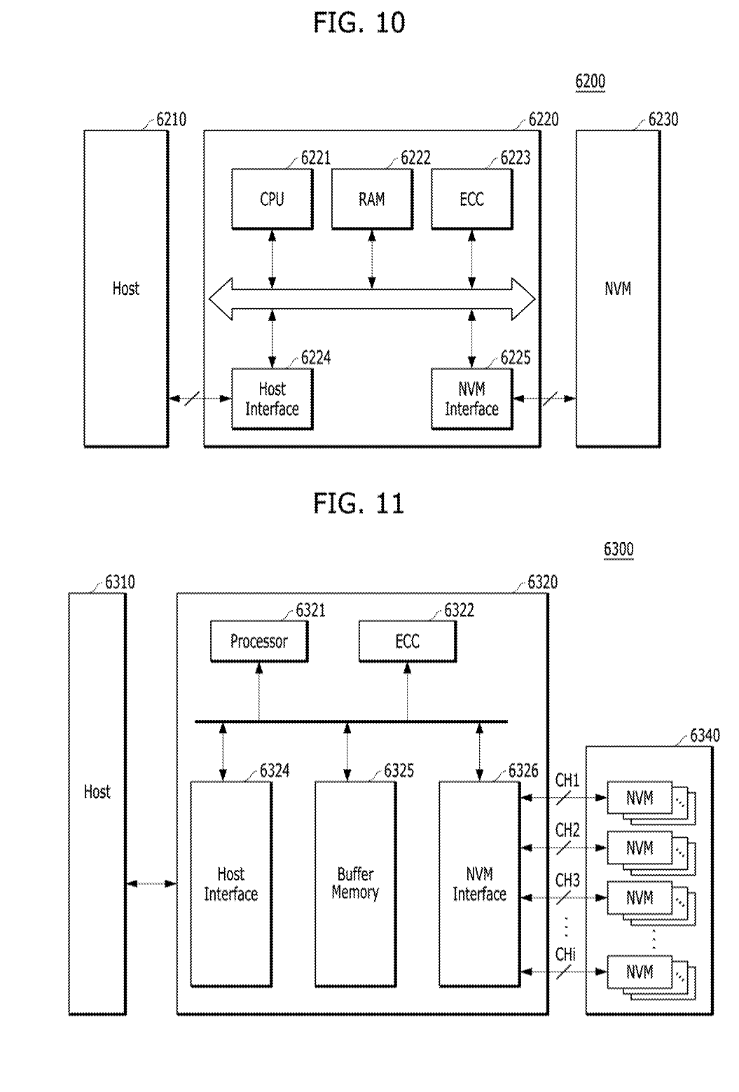

FIG. 10 is a diagram schematically illustrating an example of a data processing system including a memory system, according to an embodiment of the present invention.

Referring to FIG. 10, a data processing system 6200 includes a memory device 6230 which may be implemented with at least one nonvolatile memory (NVM) and a memory controller 6220 for controlling the memory device 6230. The data processing system 6200 may be a storage medium such as a memory card (e.g., CF, SD and microSD), as described above with reference to FIG. 1. The memory device 6230 may correspond to the memory device 150 in the memory system 110 described above with reference to FIG. 1, and the memory controller 6220 may correspond to the controller 130 in the memory system 110 described above with reference to FIG. 1.

The memory controller 6220 may control the operations, including the read, write and erase operations for the memory device 6230 in response to requests received from a host 6210. The memory controller 6220 may include a central processing unit (CPU) 6221, a random access memory (RAM) as a buffer memory 6222, an error correction code (ECC) circuit 6223, a host interface 6224, and an NVM interface as a memory interface 6225, all coupled via an internal bus.

The CPU 6221 may control the operations for the memory device 6230 such as read, write, file system management, bad page management, and so forth. The RAM 6222 may operate according to control of the CPU 6221, and may be used as a work memory, a buffer memory, a cache memory, or the like. In the case where the RAM 6222 is used as a work memory, data processed by the CPU 6221 is temporarily stored in the RAM 6222. In the case where the RAM 6222 is used as a buffer memory, the RAM 6222 is used to buffer data to be transmitted from the host 6210 to the memory device 6230 or from the memory device 6230 to the host 6210. In the case where the RAM 6222 is used as a cache memory, the RAM 6222 may be used to enable the memory device 6230 with a low speed to operate at a high speed.

The ECC circuit 6223 corresponds to the ECC unit 138 of the controller 130 described above with reference to FIG. 1. As described above with reference to FIG. 1, the ECC circuit 6223 may generate an error correction code (ECC) for correcting a fail bit or an error bit in the data received from the memory device 6230. The ECC circuit 6223 may perform error correction encoding for data to be provided to the memory device 6230, and may generate data added with parity bits. The parity bits may be stored in the memory device 6230. The ECC circuit 6223 may perform error correction decoding for data outputted from the memory device 6230. At this time, the ECC circuit 6223 may correct errors by using the parity bits. For example, as described above with reference to FIG. 1, the ECC circuit 6223 may correct errors by using various coded modulations such as of a low density parity check (LDPC) code, a Bose-Chaudhuri-Hocquenghem (BCH) code, a turbo code, a Reed-Solomon (RS) code, a convolution code, a recursive systematic code (RSC), a trellis-coded modulation (TCM) and a Block coded modulation (BCM).

The memory controller 6220 transmits and receives data to and from the host 6210 through the host interface 6224, and transmits and receives data to and from the memory device 6230 through the NVM interface 6225. The host interface 6224 may be connected with the host 6210 through at least one of various interface protocols such as a parallel advanced technology attachment (PATA) bus, a serial advanced technology attachment (SATA) bus, a small computer system interface (SCSI), a universal serial bus (USB), a peripheral component interconnection express (PCIe) or a NAND interface. Further, as a wireless communication function or a mobile communication protocol such as wireless fidelity (WI-FI) or long term evolution (LTE) is realized, the memory controller 6220 may transmit and receive data by being connected with an external device such as the host 6210 or another external device other than the host 6210. Specifically, as the memory controller 6220 is configured to communicate with an external device through at least one among various communication protocols, the memory system and the data processing system according to the embodiment may be applied to wired/wireless electronic appliances, For example, a mobile electronic appliance.

FIG. 11 is a diagram illustrating an example of a data processing system including a memory system according to an embodiment of the invention. FIG. 11 may be a solid state drive (SSD).

Referring to FIG. 11, an SSD 6300 may include a memory device 6340 which may include a plurality of nonvolatile memories NVM, and a controller 6320. The controller 6320 may correspond to the controller 130 in the memory system 110 described above with reference to FIG. 1, and the memory device 6340 may correspond to the memory device 150 in the memory system 110 described above with reference to FIG. 1.

The controller 6320 may be connected with the memory device 6340 through a plurality of channels CH1, CH2, CH3, . . . and CHi. The controller 6320 may include a processor 6321, a buffer memory 6325, an error correction code (ECC) circuit 6322, a host interface 6324, and a nonvolatile memory (NVM) interface as a memory interface 6326 coupled via an internal bus.

The buffer memory 6325 temporarily stores data received from a host 6310 or data received from a plurality of nonvolatile memories NVMs included in the memory device 6340. The buffer memory 6325 also temporarily stores metadata of the plurality of nonvolatile memories NVMs. For example, the metadata may include map data including mapping tables. The buffer memory 6325 may be implemented with a volatile memory such as, but not limited to, a dynamic random access memory (DRAM), a synchronous dynamic random access memory (SDRAM), a double data rate (DDR) SDRAM, a low power double data rate (LPDDR) SDRAM and a graphic random access memory (GRAM) or a nonvolatile memory such as, but not limited to, a ferroelectric random access memory (FRAM), a resistive random access memory (ReRAM), a spin-transfer torque magnetic random access memory (STT-MRAM) and a phase change random access memory (PRAM). While it is illustrated in FIG. 11, for the sake of convenience in explanation, that the buffer memory 6325 disposed inside the controller 6320, it is to be noted that the buffer memory 6325 may be disposed outside the controller 6320.

The ECC circuit 6322 calculates error correction code values of data to be programmed in the memory device 6340 in a program operation, performs an error correction operation for data read from the memory device 6340, based on the error correction code values, in a read operation, and performs an error correction operation for data recovered from the memory device 6340 in a recovery operation for failed data.

The host interface 6324 provides an interface function with respect to an external device such as the host 6310. The nonvolatile memory interface 6326 provides an Interface function with respect to the memory device 6340 which is connected through the plurality of channels CH1, CH2, CH3, . . . and CHi.

In an embodiment, a redundant array of independent disks (RAID) system is provided, the system including a plurality of SSDs 6300. Each SSD 6300 may employ the memory system 110 described above with reference to FIG. 1. In the RAID system, the plurality of SSDs 6300 and a RAID controller for controlling the plurality of SSDs 6300 may be included. In the case of performing a program operation by receiving a write command from the host 6310, the RAID controller may select at least one memory system (for example, at least one SSD 6300) in response to the RAID level information of the write command received from the host 6310, among a plurality of RAID levels (for example, the plurality of SSDs 6300) and may output data corresponding to the write command, to the selected SSD 6300. In the case of performing a read operation by receiving a read command from the host 6310, the RAID controller may select at least one memory system (for example, at least one SSD 6300) in response to the RAID level information of the write command received from the host 6310, among the plurality of RAID levels (for example, the plurality of SSDs 6300), and may provide data outputted from the selected SSD 6300, to the host 6310.

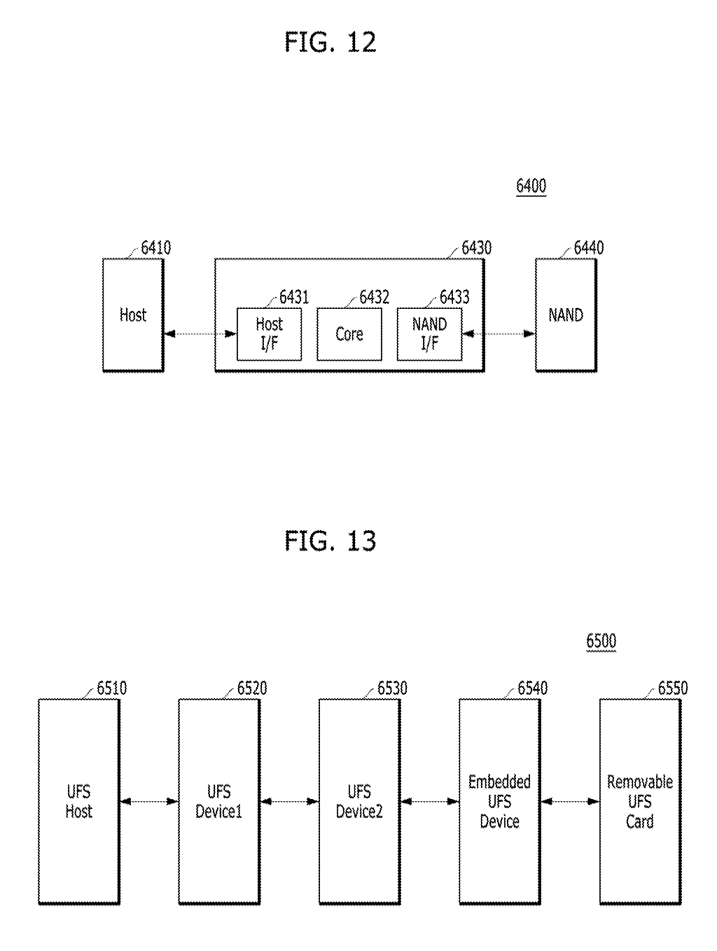

FIG. 12 illustrates an embedded multimedia card (eMMC) including a memory system according to an embodiment of the present invention.

Referring to FIG. 12, an eMMC 6400 includes a memory device 6440 which is implemented with at least one NAND flash memory, and a controller 6430. The controller 6430 may correspond to the controller 130 in the memory system 110 described above with reference to FIG. 1. The memory device 6440 may correspond to the memory device 150 in the memory system 110 described above with reference to FIG. 1.

In more detail, the controller 6430 may be connected with the memory device 6440 through a plurality of channels indicated by the two headed arrow. The controller 6430 may include a core 6432, a host interface 6431, and a memory interface 6433 such as a NAND memory interface 6433.

The core 6432 may control the operations of the eMMC 6400. The host interface 6431 may provide an interface function between the controller 6430 and a host 6410. The NAND interface 6433 may provide an interface function between the memory device 6440 and the controller 6430. For example, the host interface 6431 may be a parallel interface such as an MMC interface, as described above with reference to FIG. 1, or a serial interface such as an ultra-high speed class 1 (UHS-I)/UHS class 2 (UHS-II) and a universal flash storage (UFS) interface.

FIG. 13 is a diagram schematically illustrating a universal flash storage (UFS) system 6500 including a memory system according to an embodiment of the present invention.

Referring to FIG. 13, the UFS system 6500 may include a UFS host 6510, a plurality of UFS devices 6520 and 6530, an embedded UFS device 6540, and a removable UFS card 6550. The UFS host 6510 may be an application processor of wired/wireless electronic appliances, for example, a mobile electronic appliance.

The UFS host 6510, the UFS devices 6520 and 6530, the embedded UFS device 6540 and the removable UFS card 6550 may respectively communicate with external devices such as wired/wireless electronic appliances (for example, a mobile electronic appliance), through a UFS protocol. The UFS devices 6520 and 6530, the embedded UFS device 6540 and the removable UFS card 6550 may be implemented with the memory system 110 described above with reference to FIG. 1, for example, as the memory card system 6100 described above with reference to FIG. 9. The embedded UFS device 6540 and the removable UFS card 6550 may communicate through another protocol other than the UFS protocol. For example, the embedded UFS device 6540 and the removable UFS card 6550 may communicate through various card protocols such as, but not limited to, USB flash drives (UFDs), multimedia card (MMC), secure digital (SD), mini SD and Micro SD.

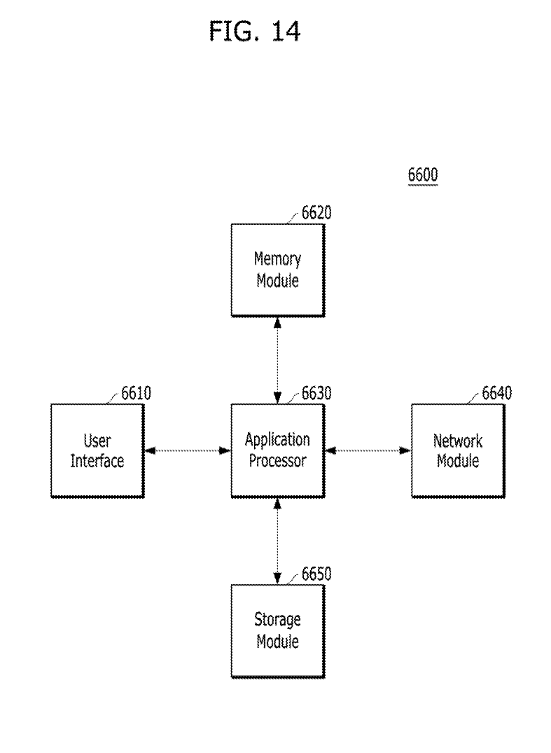

FIG. 14 is a diagram schematically illustrating a user system 6600 including a memory system, according to an embodiment of the present invention.

The user system 6600 may include an application processor 6630, a memory module 6620, a network module 6640, a storage module 6650, and a user interface 6610.

The application processor 6630 may drive components included in the user system 6600 and an operating system (OS). For example, the application processor 6630 may include controllers for controlling the components included in the user system 6600, interfaces, graphics engines, and so on. The application processor 6630 may be provided as a system-on-chip (SoC).

The memory module 6620 may operate as a main memory, a working memory, a buffer memory or a cache memory of the user system 6600. The memory module 6620 may include a volatile random access memory such as a dynamic random access memory (DRAM), a synchronous dynamic random access memory (SDRAM), a double data rate (DDR) SDRAM, a DDR2 SDRAM, a DDR3 SDRAM, a low power double data rate (LPDDR) SDRAM, an LPDDR2 SDRAM and an LPDDR3 SDRAM or a nonvolatile random access memory such as a phase change random access memory (PRAM), a resistive random access memory (ReRAM), a magnetic random access memory (MRAM) and a ferroelectric random access memory (FRAM). For example, the application processor 6630 and the memory module 6620 may be mounted by being packaged on the basis of a package-on-package (POP).

The network module 6640 may communicate with external devices. For example, the network module 6640 may support not only wired communications but also various wireless communications such as code division multiple access (CDMA), global system for mobile communication (GSM), wideband CDMA (WCDMA), CDMA-2000, time division multiple access (TDMA), long term evolution (LTE), worldwide interoperability for microwave access (WiMAX), wireless local area network (WLAN), ultra-wideband (UWB), Bluetooth, wireless display (WI-DI), and so on, and may thereby communicate with wired/wireless electronic appliances, For example, a mobile electronic appliance. Accordingly, the memory system and the data processing system may be applied to wired/wireless electronic appliances. The network module 6640 may be included in the application processor 6630.

The storage module 6650 may store data such as data received from the application processor 6530, and transmit data stored therein, to the application processor 6530. The storage module 6650 may be realized by a nonvolatile semiconductor memory device such as a phase-change RAM (PRAM), a magnetic RAM (MRAM), a resistive RAM (ReRAM), a NAND flash memory, a NOR flash memory and a 3-dimensional NAND flash memory. The storage module 6650 may be provided as a removable storage medium such as a memory card of the user system 6600 and an external drive. For example, the storage module 6650 may correspond to the memory system 110 described above with reference to FIG. 1, and may be implemented with the SSD, eMMC and UFS described above with reference to FIGS. 11 to 13.

The user interface 6610 may include interfaces for inputting data or commands to the application processor 6630 or for outputting data to an external device. For example, the user interface 6610 may include user input interfaces such as a keyboard, a keypad, a button, a touch panel, a touch screen, a touch pad, a touch ball, a camera, a microphone, a gyroscope sensor, a vibration sensor and a piezoelectric element, and user output interfaces such as a liquid crystal display (LCD), an organic light emitting diode (OLED) display device, an active matrix OLED (AMOLED) display device, a light emitting diode (LED), a speaker and a motor.

In the case where the memory system 110 described above with reference to FIG. 1 is applied to the mobile electronic appliance of the user system 6600 according to an embodiment, the application processor 6630 may control the operations of the mobile electronic appliance, and the network module 6640 as a communication module may control wired/wireless communication with an external device, as described above. The user interface 6610 as the display/touch module of the mobile electronic appliance displays data processed by the application processor 6630 or supports input of data from a touch panel.

The memory system and the operating method thereof according to the embodiments may minimize complexity and performance deterioration of the memory system and maximize use efficiency of the memory device, thereby quickly and stably process data with respect to the memory device.

Although various embodiments have been described for illustrative purposes, it will be apparent to those skilled in the art that various changes and modifications may be made without departing from the spirit and scope of the invention as defined in the following claims.

What is claimed is:

1. A memory system comprising:
a memory device including a plurality of pages, each page including a plurality of memory cells coupled with a word line, a plurality of memory blocks in which the pages are included, a plurality of planes which include the memory blocks, and a plurality of memory dies in which the planes are included; and
a controller suitable for performing at least one of a foreground operation and a background operation for the memory blocks, for checking parameters of the respective memory blocks in correspondence to performing the at least one of the foreground operation and the background operation, generating normalized parameters of the respective memory blocks, and performing the foreground operation and the background operation by using the normalized parameters of the respective memory blocks.

2. The memory system according to claim 1, wherein the controller sets, in correspondence to performing the at least one of the foreground operation and the background operation, weights for the respective memory blocks, and normalizes the parameters of the respective memory blocks by granting the weights to the parameters of the respective memory blocks.

3. The memory system according to claim 2, wherein the weights for the respective memory blocks depend upon the stress levels in the respective memory blocks, when performing the at least one of the foreground operation and the background operation.

4. The memory system according to claim 3, wherein the stress levels for the respective memory blocks depend upon at least one of an operational characteristic and a structural characteristic of the respective memory blocks.

5. The memory system according to claim 4, wherein, among the memory blocks, the controller sets a first weight to first memory blocks which have a first stress level, sets a second weight to second memory blocks which have a second stress level, and sets a third weight to third memory blocks which have a third stress level.

6. The memory system according to claim 5,
wherein the first memory blocks are single level cell (SLC) memory blocks,
wherein the second memory blocks are multi-level cell (MLC) memory blocks, and
wherein the third memory blocks are triple level cell (TLC) memory blocks.

7. The memory system according to claim 1, wherein, after performing the at least one of the foreground operation and the background operation by using the normalized parameters, the controller updates the parameters and the normalized parameters of the respective memory blocks.

8. The memory system according to claim 1,
wherein the foreground operation includes at least one of a program operation, a read operation, an erase operation and a parameter set operation for the memory blocks, and
wherein the background operation includes at least one of a data copy operation, a data swap operation, a map flush operation and a bad block management operation for the memory blocks.

9. The memory system according to claim 8, wherein the controller selects a first memory block and a second memory block among the memory blocks, by using the normalized parameters of the respective memory blocks, and performs the data copy operation or the data swap operation for the first memory block and the second memory block.

10. The memory system according to claim 8, wherein the at least one parameter includes an operation parameter and a state parameter in the respective memory blocks when performing the foreground operation and the background operation.

11. A method for operating a memory system, comprising:
performing at least one of a foreground operation and a background operation for a plurality of memory blocks of a memory device, including a plurality of pages each page including a plurality of memory cells which are coupled to a word line;
checking a parameter for each of the respective memory blocks in correspondence to performing the foreground operation and the background operation;
normalizing the parameters of the respective memory blocks and generating a normalized parameter for each of the respective memory blocks; and
performing the at least one of the foreground operation and the background operation by using the normalized parameter for each of the respective memory blocks.

12. The method according to claim 11, further comprising:
setting, in correspondence to performing the at least one of the foreground operation and the background operation, a weight for each of the respective memory blocks,
wherein the generating of the normalized parameter includes normalizing the parameter for each of respective memory blocks by granting the weights to the parameters of the respective memory blocks.

13. The method according to claim 12, wherein the setting of the weight includes setting the weight for each of the respective memory blocks depending upon a stress level for each of the respective memory blocks, when performing the at least one of the foreground operation and the background operation.

14. The method according to claim 13, wherein the stress level for each of the respective memory blocks depends upon at least one of an operational characteristic and a structural characteristic for each of the respective memory blocks.

15. The method according to claim 14, wherein the setting of the weight includes setting a first weight for first memory blocks which have a first stress level, setting a second weight for second memory blocks which have a second stress level, and setting a third weight for third memory blocks which have a third stress level.

16. The method according to claim 15,
wherein the first memory blocks are single level cell (SLC) memory blocks, the second memory blocks are multi-level cell (MLC) memory blocks, and the third memory blocks are triple level cell (TLC) memory blocks.

17. The method according to claim 11, further comprising:
updating the parameter and the normalized parameter for each of the respective memory blocks, after performing the at least one of the foreground operation and the background operation by using the normalized parameters.

18. The method according to claim 11,
wherein the foreground operation includes at least one of a program operation, a read operation, an erase operation and a parameter set operation for the memory blocks, and the background operation includes at least one of a data copy operation, a data swap operation, a map flush operation and a bad block management operation in the memory blocks.

19. The method according to claim 18, wherein the performing of the background operation comprises:
selecting a first memory block and a second memory block among the memory blocks, by using the normalized parameters of the respective memory blocks; and
performing the data copy operation or the data swap operation for the first memory block and the second memory block.

20. The method according to claim 18, wherein the parameter includes at least one of an operation parameter and a state parameter for each of the respective memory blocks when performing the at least one of the foreground operation and the background operation.
